(19) United States
(12) Patent Application Publication
(10) Pub. No.: US 2012/0080220 A1
(43) Pub. Date: Apr. 5, 2012

(54) ELECTRONIC DEVICE, CIRCUIT BOARD, AND MANUFACTURING METHOD OF ELECTRONIC DEVICE

(75) Inventors: Kimio NAKAMURA, Kawasaki (JP); Shuichi TAKEUCHI, Kawasaki (JP); Yoshiyuki SATOH, Kawasaki (JP); Kenji KOBAE, Kawasaki (JP)

(73) Assignee: FUJITSU LIMITED, Kawasaki-shi (JP)

(21) Appl. No.: 13/196,317

(22) Filed: Aug. 2, 2011

(30) Foreign Application Priority Data
Sep. 30, 2010 (JP) 2010-223298

(51) Int. Cl. H05K 1/18; H05K 13/00

(52) U.S. Cl. 174/260; 29/829

(57) ABSTRACT

An electronic device includes a circuit board including a first electrode and a second electrode; and an electronic component including a first terminal and a second terminal, wherein the first electrode includes a first pad portion to which the first terminal is connected and a first protrusion portion disposed in a first direction in parallel with a straight line passing through the first electrode and the second electrode with respect to the first pad portion and being into contact with the first terminal, the second electrode includes a second pad portion to which the second terminal is connected and a second protrusion portion disposed in a second direction opposite to the first direction with respect to the second pad portion and being into contact with the second terminal.

### CROSS-REFERENCE TO RELATED APPLICATION

This application is based upon and claims the benefit of priority of the prior Japanese Patent Application No. 2010-223298, filed on Sep. 30, 2010, the entire contents of which are incorporated herein by reference.

### FIELD

The embodiment discussed herein is related to an electronic device in which an electronic component is flip-chip mounted on a circuit board, a circuit board, and a manufacturing method of the electronic device.

### BACKGROUND

As electronic devices become smaller, thinner, and denser, the pitch of electrode pads formed on a circuit board becomes finer. As the pitch becomes finer, the electrode pad itself becomes narrower, and when an electronic component is flip-chip mounted on a circuit board, it becomes difficult to reliably mount terminals of the electronic component on the electrode pads on the circuit board. To solve the problem, for example, a technique is known in which an opening (concave portion) is formed in the electrode pad of the circuit board and a terminal of a semiconductor element is introduced into the opening while being slid along the inner edge of the opening.

Japanese Laid-open Patent Publication No. 2008-21751 and Japanese Laid-open Patent Publication No. 2005-353854 are examples of related art.

To form an opening in the electrode pad, it is necessary to form a wall portion that defines the opening in the electrode pad. Therefore, the electrode pad needs to be widened by at least the width of the wall portion. This prevents the pitch of the electrode pads from becoming finer.

### SUMMARY

According to an aspect of the invention, an electronic device includes a circuit board including a first electrode and a second electrode; and an electronic component including a first terminal and a second terminal, wherein the first electrode includes a first pad portion to which the first terminal is connected and a first protrusion portion disposed in a first direction in parallel with a straight line passing through the first electrode and the second electrode with respect to the first pad portion and being into contact with the first terminal, the second electrode includes a second pad portion to which the second terminal is connected and a second protrusion portion disposed in a second direction opposite to the first direction with respect to the second pad portion and being into contact with the second terminal, a central axis of the first terminal is disposed on a side of the first pad portion with respect to the first protrusion portion, and a central axis of the second terminal is disposed on a side of the second pad portion with respect to the second protrusion portion.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view of a semiconductor device according to a first embodiment.

FIG. 2 is a cross-sectional view of the semiconductor device according to the first embodiment.

FIG. 3 is a bottom view of a semiconductor chip according to the first embodiment.

FIGS. 4A and 4B are cross-sectional views of the semiconductor chip according to the first embodiment.

FIG. 5 is a top view of a circuit board according to the first embodiment.

FIG. 6 is a cross-sectional view of the circuit board according to the first embodiment.

FIGS. 7A and 7B are illustrations for explaining a manufacturing method of the semiconductor device according to the first embodiment.

FIGS. 8A and 8B are illustrations for explaining the manufacturing method of the semiconductor device according to the first embodiment.

FIGS. 9A and 9B are illustrations for explaining a positioning process of the semiconductor chip according to the first embodiment.

FIGS. 10A and 10B are illustrations for explaining the positioning process of the semiconductor chip according to the first embodiment.

FIG. 11 is an illustration for explaining positioning of the semiconductor chip according to the first embodiment.

FIG. 12 is a cross-sectional view of a semiconductor device according to a modified example of the first embodiment.

FIG. 13 is a top view of a circuit board according to the modified example of the first embodiment.

FIG. 14 is a cross-sectional view of a circuit board according to the modified example of the first embodiment.

FIG. 15 is a cross-sectional view of a semiconductor device according to a second embodiment.

FIG. 16 is a top view of a circuit board according to the second embodiment.

FIGS. 17A and 17B are illustrations for explaining a positioning process of a semiconductor chip according to the second embodiment.

FIGS. 18A and 18B are illustrations for explaining the positioning process of the semiconductor chip according to the second embodiment.

FIG. 19 is an illustration for explaining positioning of the semiconductor chip according to the second embodiment.

FIG. 20 is an illustration for explaining positioning of a semiconductor chip according to a modified example 1 of the second embodiment.

FIG. 21 is an illustration for explaining positioning of a semiconductor chip according to a modified example 2 of the second embodiment.

FIG. 22 is a cross-sectional view of a semiconductor device according to a third embodiment.

FIG. 23 is a top view of a circuit board according to the third embodiment.

FIG. 24 is a cross-sectional view of the circuit board according to the third embodiment.

FIGS. 25A to 25C are illustrations for explaining a manufacturing method of the circuit board according to the third embodiment.

FIGS. 26A and 26B are illustrations for explaining a manufacturing method of the semiconductor device according to the third embodiment.

FIGS. 27A and 27B are illustrations for explaining the manufacturing method of the semiconductor device according to the third embodiment.

FIGS. 28A to 28C are illustrations for explaining a positioning process of a semiconductor chip according to the third embodiment.

FIG. 29 is a cross-sectional view of a semiconductor device according to a modified example of the third embodiment.

FIG. 30 is a cross-sectional view of a circuit board according to the modified example of the third embodiment.

### DESCRIPTION OF EMBODIMENTS

### First Embodiment

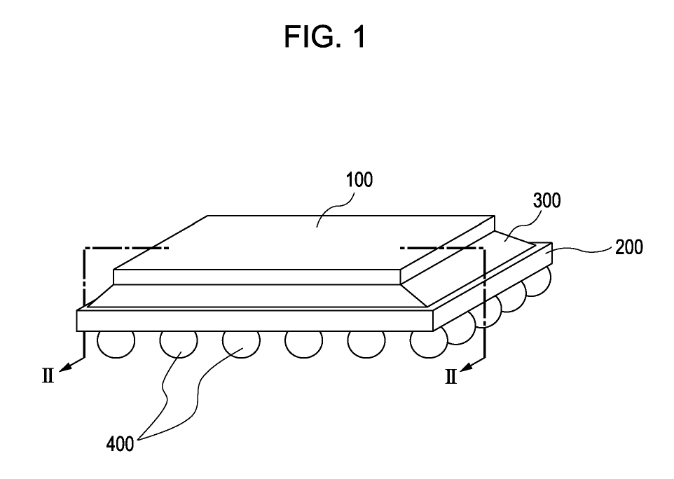

Hereinafter, a first embodiment will be described with reference to FIGS. 1 to 11.

Configuration of Semiconductor Device

First, a configuration of a semiconductor device will be described with reference to FIGS. 1 to 6.

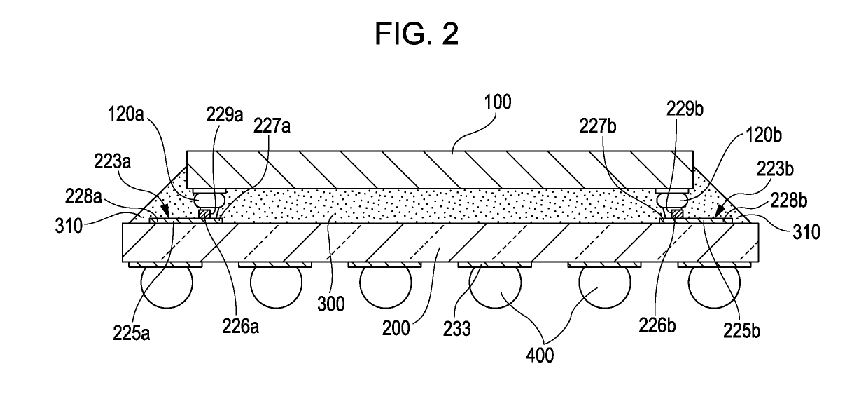

FIG. 1 is a perspective view of the semiconductor device according to the first embodiment. FIG. 2 is a cross-sectional view of the semiconductor device according to the first embodiment and illustrates a cross-section taken along line II-II in FIG. 1.

As illustrated in FIG. 1 or FIG. 2, the semiconductor device is a so-called BGA (Ball Grid Array) type semiconductor package, and includes a semiconductor chip 100, a circuit board 200 on which the semiconductor device 100 is mounted, an underfill resin 300 filled in a gap between the semiconductor chip 100 and the circuit board 200, and solder balls 400 attached to the circuit board 200 as external connection terminals.

Configuration of Semiconductor Chip

The semiconductor chip 100 is assumed to be a chip formed by forming a plurality of element areas on a semiconductor wafer and dicing the semiconductor wafer into chips. However, the present embodiment is not limited to a semiconductor chip, but other electronic components may be used.

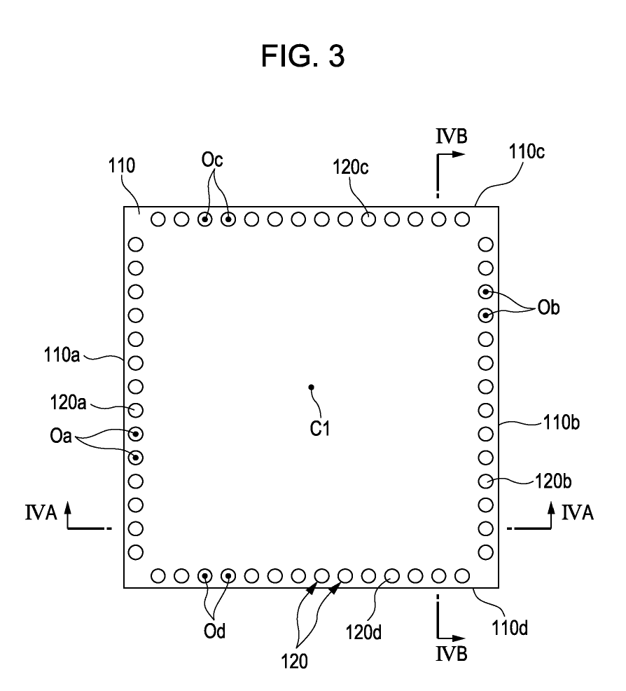

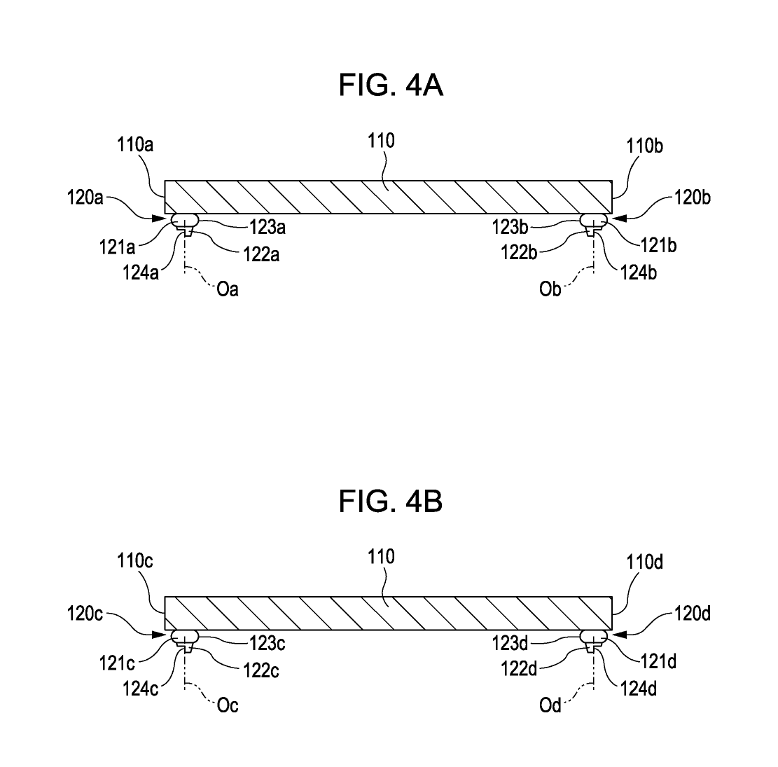

FIG. 3 is a bottom view of the semiconductor chip 100 according to the first embodiment. FIG. 4A is a cross-sectional view of the semiconductor chip 100 according to the first embodiment and illustrates a cross-section taken along line IVA-IVA in FIG. 3. FIG. 4B is a cross-sectional view of the semiconductor chip 100 according to the first embodiment and illustrates a cross-section taken along line IVB-IVB in FIG. 3.

As illustrated in FIGS. 3, 4A, and 4B, the semiconductor chip 100 includes a chip main body 110 and a plurality of bumps 120.

The chip main body 110 is formed into a substantially rectangular shape in a plan view, and includes a first chip edge 110a, a second chip edge 110b, a third chip edge 110c, and a fourth chip edge 110d. The first chip edge 110a and the second chip edge 110b are disposed on the sides opposite to each other with respect to the center C1 of the semiconductor chip 100 and extend in parallel with each other. The third chip edge 110c and the fourth chip edge 110d are disposed on the sides opposite to each other with respect to the center C1 of the semiconductor chip 100 and extend in parallel with each other and perpendicular to the first chip edge 110a and the second chip edge 110b.

The lengths of the first to the fourth chip edges 110a to 110d are all set to 4 mm. The thickness of the chip main body 110 is set to about 0.2 mm. However the present embodiment is not limited to the above. For example, the chip main body 110 may have a rectangular solid shape, a triangular shape, a pentagonal shape, other polygonal more than pentagonal shapes, a circular shape, or an elliptical shape in a plan view.

The plurality of bumps 120 are classified into first bumps 120a, second bumps 120b, third bumps 120c, and fourth bumps 120d. The first to the fourth bumps 120a to 120d have the same number of bumps and the same pitch, and are respectively arranged along the first to the fourth chip edges 110a to 110d. The first to the fourth bumps 120a to 120d are arranged so that the distance between the first bumps 120a and the second bumps 120b is the same as the distance between the third bumps 120c and the fourth bumps 120d.

The first to the fourth bumps 120a to 120d respectively include first portions 121a to 121d connected to the chip main body 110 and second portions 122a to 122d connected to the first portions 121a to 121d.

The first portions 121a to 121d are formed into a substantially cylindrical shape, and first to fourth maximum diameter portions 123a to 123d are respectively formed at middle positions thereof in the cylindrical axis direction. The second portions 122a to 122d are formed so that the diameter thereof decreases as the distance from the chip main body 110 increases, in other words, formed into a taper shape. The second portions 122a to 122d respectively include first to fourth lost portions 124a to 124d on the outer side of the chip main body 110, in other words, on the sides of the first to the fourth chip edges 110a to 110d. The first to the fourth lost portions 124a to 124d are formed when the semiconductor chip 100 is mounted on a circuit board 200 described below, and respectively have shapes corresponding to first to fourth top surface electrodes 223a to 223d of a circuit board 200 described below, in other words, shapes corresponding to first to fourth protrusion portions 226a to 226d.

The first portions 121a to 121d and the second portions 122a to 122d are formed of the same material. As a material of the first to the fourth bumps 120a to 120d, for example, a metal such as gold is used. As a manufacturing method of the first to the fourth bumps 120a to 120d, for example, a ball bonding may be used.

In the present embodiment, the numbers of the first to the fourth bumps 120a to 120d are all the same. However the present embodiment is not limited to this. For example, if the number of the first bumps 120a is the same as the number of the second bumps 120b and the number of the third bumps 120c is the same as the number of the fourth bumps 120d, it is not necessary that the numbers of the first to the fourth bumps 120a to 120d are all the same.

In the present embodiment, the first to the fourth bumps 120a to 120d are all arranged at the same pitch. However the present embodiment is not limited to this. For example, if the first bumps 120a and the second bumps 120b are arranged at the same pitch and the third bumps 120c and the fourth bumps 120d are arranged at the same pitch, it is not necessary that the first to the fourth bumps 120a to 120d are all arranged at the same pitch.

Further, in the present embodiment, the first to the fourth bumps 120a to 120d are arranged so that the distance between the first bumps 120a and the second bumps 120b is the same as the distance between the third bumps 120c and the fourth bumps 120d. However the present embodiment is not limited to this. For example, according to the shape and the design of the semiconductor chip 100, the first to the fourth bumps 120a to 120d may be arranged so that the distance between the first bumps 120a and the second bumps 120b is different from the distance between the third bumps 120c and the fourth bumps 120d.

Configuration of Circuit Board

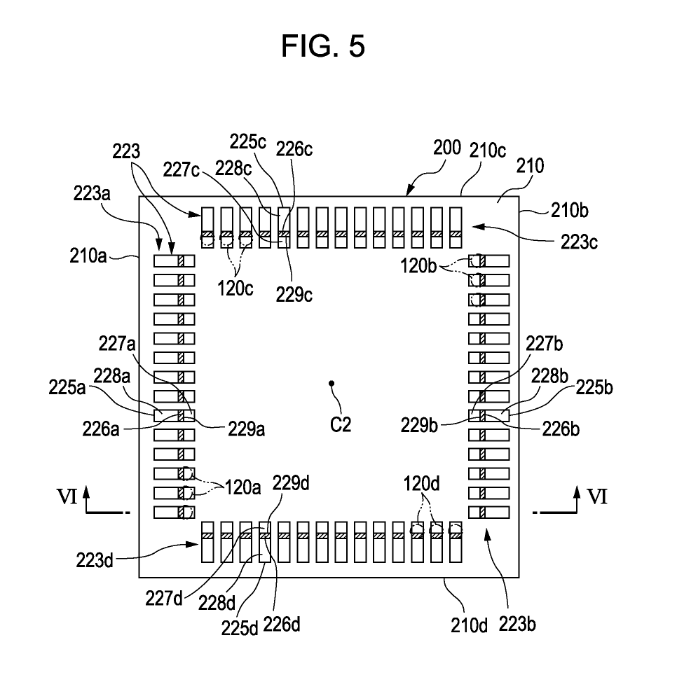

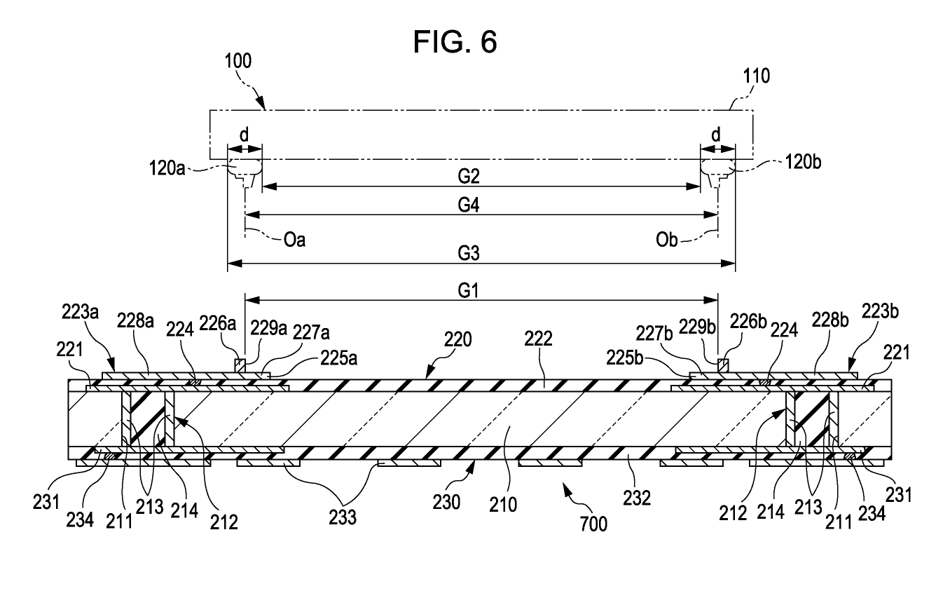

FIG. 5 is a top view of the circuit board 200 according to the first embodiment. FIG. 6 is a cross-sectional view of the circuit board 200 according to the first embodiment and illustrates a cross-section taken along line VI-VI in FIG. 5. In FIG. 5, the first to the fourth bumps 120a to 120d are illustrated by virtual lines (two-dot chain lines). However, for clarification of the drawing, the number of the bumps illustrated in the drawing is limited to three for each of the first to the fourth bumps 120a to 120d.

The circuit board 200 is a so-called glass epoxy board. However, the present embodiment is not limited to this, but other printed boards, for example, a glass composite board and a ceramic board may be used.

As illustrated in FIGS. 5 and 6, the circuit board 200 includes a core member 210, a top surface wiring layer 220, and a bottom surface wiring layer 230.

The core member 210 is, for example, a glass cloth impregnated with an epoxy resin. The core member 210 is formed into a substantially rectangular shape in a plan view, and includes a first board edge 210a, a second board edge 210b, a third board edge 210c, and a fourth board edge 210d. The first board edge 210a and the second board edge 210b are disposed on the sides opposite to each other with respect to the center C2 of the circuit board 200 and extend in parallel with each other. The third board edge 210c and the fourth board edge 210d are disposed on the sides opposite to each other with respect to the center C2 of the circuit board 200 and extend in parallel with each other and perpendicular to the first board edge 210a and the second board edge 210b.

A plurality of through holes 211 are formed at predetermined positions in the core member 210. The through hole 211 vertically penetrates the core member 210, and a via 212 is buried inside the through hole 211. The via 212 includes a conductive film 213 formed on inner surface of the through hole 211 and an insulating member 214 filled inside the insulating film 213. The conductive film 213 connects the top surface wiring layer 220 and the bottom surface wiring layer 230 with each other so that the both wiring layers are electrically connected with each other. As a material of the conductive layer 213, for example, Cu may be used. As a material of the insulating member 214, for example, a polyimide system resin or an epoxy system resin may be used.

The top surface wiring layer 220 is formed on the top surface of the core member 210, that is, a surface facing the semiconductor chip 100, and includes a top surface wiring pattern 221, a top surface insulating film 222, and a plurality of top surface electrodes 223 in the order from the core member 210.

The top surface wiring pattern 221 is formed on the top surface of the core member 210. As a material of the top surface wiring pattern 221, for example, a metal such as Cu is used. The manufacturing method of the top surface wiring pattern 221 is not particularly limited. For example, after a metal foil such as a Cu foil is formed on the entire top surface of the core member 210, a resist pattern is formed by a photolithography technique, and the metal foil may be etched by using the resist pattern as a mask.

The top surface insulating film 222 is formed between the top surface wiring pattern 221 and a layer of the top surface electrodes 223. As a material of the top surface insulating film 222, for example, an epoxy system resin or a polyimide system resin may be used. A plurality of vias 224 are buried at predetermined positions in the top surface insulating film 222. The via 224 vertically penetrates the top surface insulating film 222 and electrically connects the top surface wiring pattern 221 with the top surface electrode 223. As a material of the via 224, for example, a metal such as Cu may be used.

The plurality of top surface electrodes 223 are classified into first top surface electrodes 223a, second top surface electrodes 223b, third top surface electrodes 223c, and fourth top surface electrodes 223d. The number and the pitch of the first to the fourth top surface electrodes 223a to 223d are the same as those of the first to the fourth bumps 120a to 120d of the semiconductor chip 100, and are respectively arranged along the first to the fourth board edges 210a to 210d. The first to the fourth top surface electrodes 223a to 223d are arranged so that the distance between the first top surface electrodes 223a and the second top surface electrodes 223b is the same as the distance between the third top surface electrodes 223c and the fourth top surface electrodes 223d.

The first to the fourth top surface electrodes 223a to 223d respectively include first to fourth pad portions 225a to 225d and first to fourth protrusion portions 226a to 226d arranged on the first to the fourth pad portions 225a to 225d. In FIG. 5, for clarification of the drawing, the first to the fourth protrusion portions 226a to 226d are shaded. This is the same in other embodiments.

The first to the fourth pad portions 225a to 225d are formed into a rectangle shape and respectively arranged to be perpendicular to the first to the fourth board edges 210a to 210d. As a material of the first to the fourth pad portions 225a to 225d, an electrically conductive material, for example, a metal such as Cu may be used.

The first to the fourth protrusion portions 226a to 226d are respectively arranged in a middle position in the longitudinal direction of the first to the fourth pad portions 225a to 225d, and define first to fourth mounting portions 227a to 227d and first to fourth extending portions 228a to 228d on the first to the fourth pad portions 225a to 225d. As a material of the first to the fourth protrusion portions 226a to 226d, an electrically conductive material or an insulating material having rigidity higher than that of the first to the fourth bumps 120a to 120d of the semiconductor chip 100 is used. As the electrically conductive material, for example, a metal such as Cu may be used. As the insulating material, for example, a resin such as an epoxy resin may be used.

The first to the fourth mounting portions 227a to 227d are areas on which the first to the fourth bumps 120a to 120d of the semiconductor chip 100 are mounted, and are arranged on the inner side of the circuit board 200 with respect to the first to the fourth protrusion portions 226a to 226d, respectively. The first to the fourth extending portions 228a to 228d are arranged on the outer side of the circuit board 200 with respect to the first to the fourth protrusion portions 226a to 226d, respectively.

The first to the fourth protrusion portions 226a to 226d respectively include first to fourth restriction surfaces 229a to 229d at portions facing the inner side of the circuit board 200. The first to the fourth restriction surfaces 229a to 229d respectively extend in parallel with the first to the fourth board edges 210a to 210d, and restrict the first to the fourth bumps 120a to 120d of the semiconductor chip 100 from moving in a direction parallel with the mounting surface of the circuit board 200.

The first to the fourth protrusion portions 226a to 226d are arranged so that the distance between the first restriction surfaces 229a and the second restriction surfaces 229b is the same as the distance between the third restriction surfaces 229c and the fourth restriction surfaces 229d.

The first to the fourth bumps 120a to 120d of the semiconductor chip 100 are arranged to be mounted from the inner side to the outer side of the circuit board 200 with respect to the first to the fourth restriction surfaces 229a to 229d respectively, and connected to the first to the fourth mounting portions 227a to 227d and the first to the fourth protrusion portions 226a to 226d.

Therefore, the distance G1 between the first restriction surface 229a and the second restriction surface 229b is greater than the distance G2 between the first bump 120a and the second bump 120b, and smaller than the distance G3 obtained by adding two times the diameter d of the first and the second bumps 120a and 120b (=2d) to the distance G2 between the first bump 120a and the second bump 120b. Similarly, the distance G1 between the third restriction surface 229c and the fourth restriction surface 229d is greater than the distance G2 between the third bump 120c and the fourth bump 120d, and smaller than the distance G3 obtained by adding two times the diameter d of the third and the fourth bumps 120c and 120d (=2d) to the distance G2 between the third bump 120c and the fourth bump 120d.

Further, the first to the fourth bumps 120a to 120d are arranged so that the central axes Oa to Od thereof are located on the inner side of the circuit board 200 with respect to the first to the fourth regulation surfaces 229a to 229d respectively.

Therefore, the distance G1 between the first restriction surface 229a and the second restriction surface 229b is greater than the distance G4 between the central axis Oa of the first bump 120a and the central axis Ob of the second bump 120b. Although not illustrated in the drawings, the distance G1 between the third restriction surface 229c and the fourth restriction surface 229d is greater than the distance G4 between the central axis Oc of the third bump 120c and the central axis Od of the fourth axis 120d.

The bottom surface wiring layer 230 is formed on the bottom surface of the core member 210, that is, a surface on which the solder balls 400 are attached, and includes a bottom surface wiring pattern 231, a bottom surface insulating film 232, and a plurality of bottom surface electrodes 233 in the order from the core member 210.

The bottom surface wiring pattern 231 is formed on the bottom surface of the core member 210. As a material of the bottom surface wiring pattern 231, for example, a metal such as Cu may be used. The manufacturing method of the bottom surface wiring pattern 231 is not particularly limited. For example, after a metal foil such as a Cu foil is formed on the entire bottom surface of the core member 210, a resist pattern is formed by a photolithography technique, and the metal foil may be etched by using the resist pattern as a mask.

The bottom surface insulating film 232 is formed between the bottom surface wiring pattern 231 and a layer of the bottom surface electrodes 233. As a material of the bottom surface insulating film 232, for example, an epoxy system resin or a polyimide system resin may be used. A plurality of vias 234 are buried at predetermined positions in the bottom surface insulating film 232. The via 234 vertically penetrates the bottom surface insulating film 232 and electrically connects the bottom surface wiring pattern 231 with the bottom surface electrode 233. As a material of the via 234, for example, a metal such as Cu may be used.

The plurality of bottom surface electrodes 233 are arranged in a matrix form on the entire bottom surface of the circuit board 200. The solder balls 400 are respectively attached to the bottom surface electrodes 233. The solder balls 400 function as external connection terminals when the semiconductor device is mounted on another mounting board (mother board).

As illustrated in FIGS. 1 and 2, the underfill resin 300 is filled in a gap between the semiconductor chip 100 and the circuit board 200, and connects the semiconductor chip 100 with the circuit board 200. The underfill resin 300 presses the first to the fourth bumps 120a to 120d of the semiconductor chip 100 onto the first to the fourth top surface electrodes 223a to 223d of the circuit board 200 by a contractile force generated when the material of the underfill resin 300 is solidified, and electrically connects the first to the fourth bumps 120a to 120d with the first to the fourth top surface electrodes 223a to 223d. Therefore, it is not necessary to use a separate electrically-conductive adhesive material when connecting the first to the fourth bumps 120a to 120d with the first to the fourth top surface electrodes 223a to 223d. The marginal portion of the underfill resin 300 protrude to the area surrounding the semiconductor chip 100 and forms a so-called fillet 310. The fillet 310 reaches from the top surface of the circuit board 200 to the side surface of the semiconductor chip 100 and increases bonding force between the semiconductor chip 100 and the circuit board 200. As the underfill resin 300, for example, an epoxy system resin, specifically, a material in which fillers made of silica is added to an epoxy resin may be used.

Manufacturing Method of Semiconductor Device

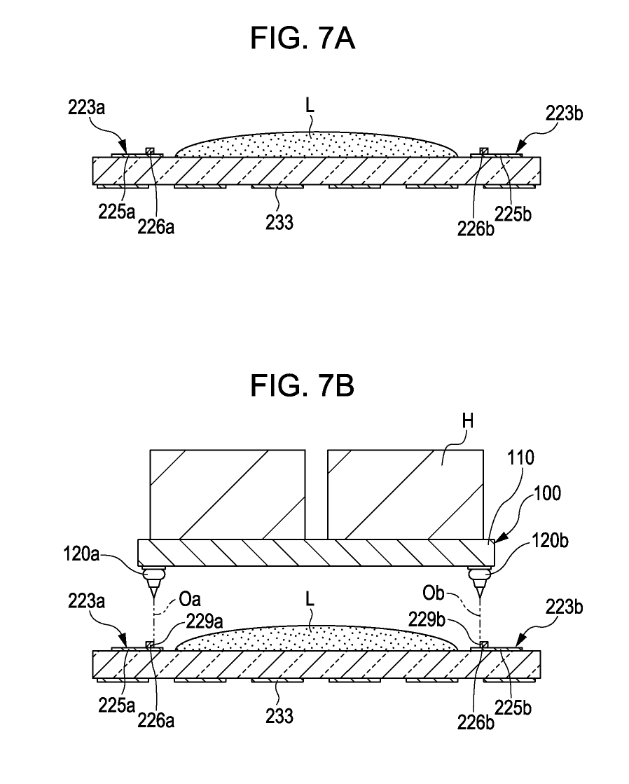

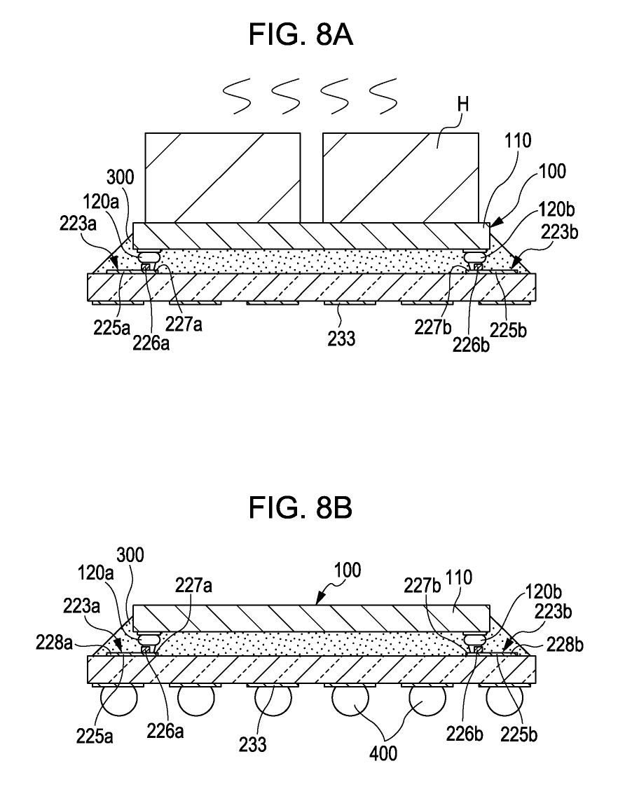

Next, a manufacturing method of the semiconductor device will be described with reference to FIGS. 7A, 7B, 8A, and 8B.

FIGS. 7A, 7B, 8A, and 8B are illustrations for explaining the manufacturing method of the semiconductor device according to the first embodiment.

First, as illustrated in FIG. 7A, an epoxy system resin L is provided to the top surface of the circuit board 200 by, for example, a dispense method. The epoxy system resin L is, for example, a material in which fillers made of silica is added to an epoxy resin.

Next, as illustrated in FIG. 7B, the semiconductor chip 100 is absorbed to the bottom surface of a pressure head H, and the semiconductor chip 100 is positioned so that the central axes Oa to Od of the first to the fourth bumps 120a to 120d are located on the inner side of the circuit board 200 with respect to the first to the fourth regulation surfaces 229a to 229d respectively. At this time, the first to the fourth bumps 120a to 120d are formed into a conical shape in which the diameter thereof decreases as the distance from the chip main body 110 increases. In other words, the first to the fourth bumps 120a to 120d respectively have a sharp top end portion.

Next, as illustrated in FIG. 8A, the pressure head H that absorbs the semiconductor chip 100 is lowered and the semiconductor chip 100 is moved closer to the circuit board 200. Thereby the epoxy system resin L provided on the circuit board 200 is pressed and spread by the semiconductor chip 100 and the gap between the semiconductor chip 100 and the circuit board 200 is filled.

When the first to the fourth bumps 120a to 120d come into contact with the first to the fourth top surface electrodes 223a to 223d, the semiconductor chip 100 is started to be pressed onto the circuit board 200. The pressure weight at this time is set to, for example, 2 kgf to 8 kgf even though it depends on the size of the semiconductor chip 100, the size of the first to the fourth bumps 120a to 120d, and the number of the first to the fourth bumps 120a to 120d. In this way, the first to the fourth bumps 120a to 120d are accurately positioned with respect to the first to the fourth top surface electrodes 223a to 223d through a positioning process described below. When the first to the fourth bumps 120a to 120d are accurately positioned, the semiconductor chip 100 is also accurately positioned with respect to the circuit board 200.

Then, the semiconductor chip 100 is further pressed, and the first to the fourth bumps 120a to 120d are respectively connected to the first to the fourth protrusion portions 226a to 226d and the first to the fourth mounting portions 227a to 227d. At this time, the first to the fourth bumps 120a to 120d are deformed according to the shapes of the first to the fourth protrusion portions 226a to 226d and the first to the fourth mounting portions 227a to 227d. Thereby the sharp top end portions of the first to the fourth bumps 120a to 120d are flattened and the first to the fourth lost portions 124a to 124d are formed on the inner side of the semiconductor chip 100.

When the first to the fourth bumps 120a to 120d are respectively connected to the first to the fourth protrusion portions 226a to 226d and the first to the fourth mounting portions 227a to 227d, the semiconductor chip 100 is heated by a heater (not illustrated in the drawings) provided in the pressure head H to solidify the epoxy system resin L in the gap between the semiconductor chip 100 and the circuit board 200. Thereby the epoxy system resin L contracts, and the semiconductor chip 100 and the circuit board 200 are bonded together.

Next, as illustrated in FIG. 8B, the solder balls 400 are respectively attached to the bottom surface electrodes 233 of the circuit board 200. In this way, the semiconductor device according to the first embodiment is completed.

Positioning Process of Semiconductor Chip

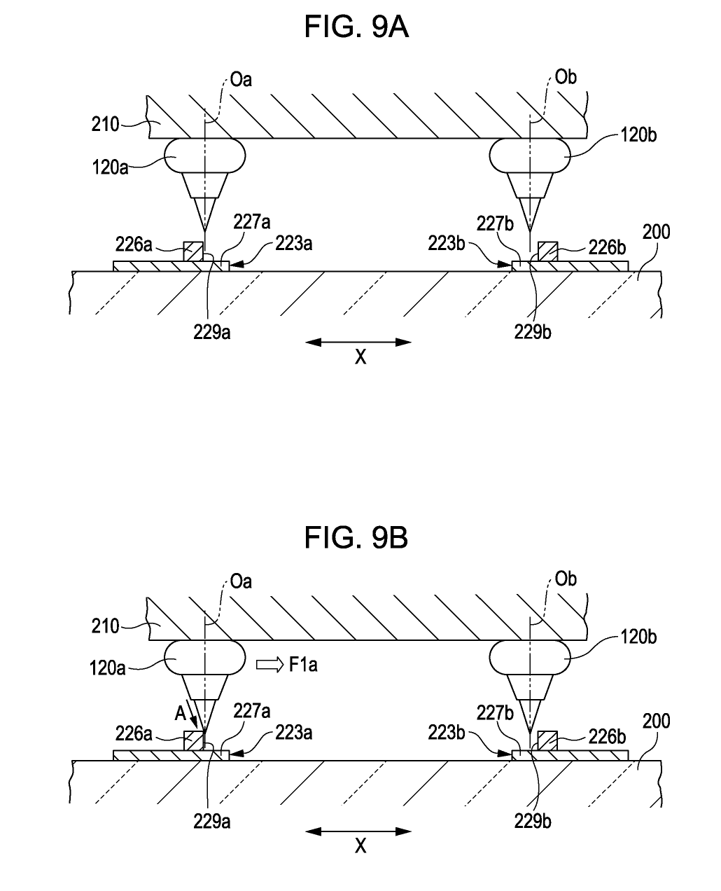

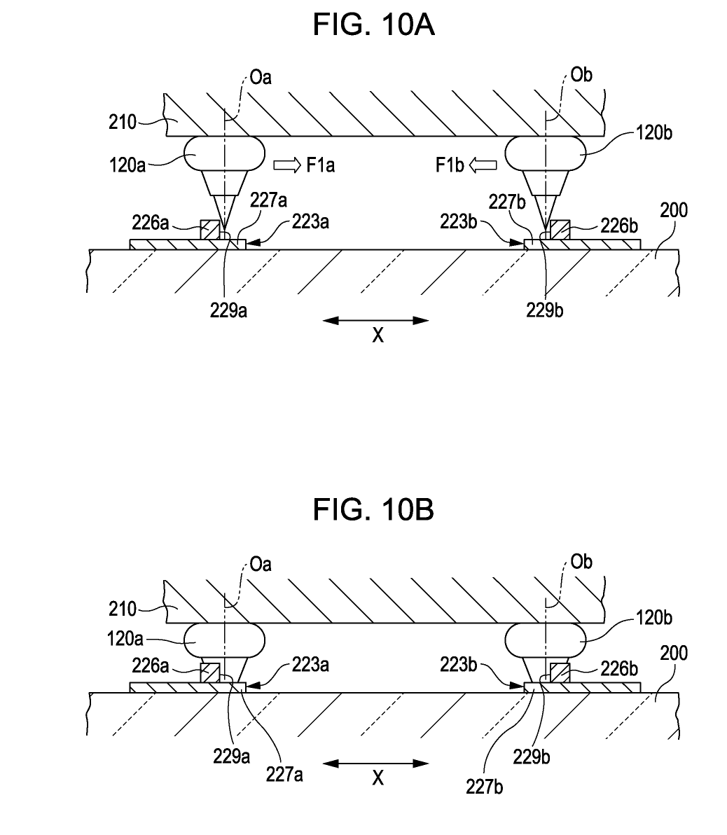

Next, the positioning process of the semiconductor chip 100 will be described with reference to FIGS. 9A, 9B, 10A, and 10B.

FIGS. 9A, 9B, 10A, and 10B are illustrations for explaining the positioning process of the semiconductor chip 100 according to the first embodiment, and illustrate the cooperation between the first and the second bumps 120a and 120b and the first and the second top surface electrodes 223a and 223b.

First, as illustrated in FIG. 9A, the pressure head H (not illustrated in FIG. 9A) that absorbs the semiconductor chip 100 is driven to position the semiconductor chip 100 so that the central axes Oa to Od of the first to the fourth bumps 120a to 120d are located on the inner side of the circuit board 200 with respect to the first to the fourth regulation surfaces 229a to 229d. However, the absorbing surface of the pressure head H has a small static friction coefficient, so the position of the absorbed semiconductor chip 100 may be shifted on the absorbing surface of the pressure head H. Therefore, even when the semiconductor chip 100 is positioned by driving the pressure head H, the actual position of the semiconductor chip 100 may be slightly shifted from the correct position. Considering this, in the description below, it is assumed that the semiconductor chip 100 is slightly shifted toward the first board edge 210a (toward the left side in FIGS. 9A and 9B) in the X direction of the circuit board 200.

Next, the pressure head H is lowered and the semiconductor chip 100 is moved closer to the circuit board 200. At this time, if the semiconductor chip 100 is shifted toward the first board edge 210a (toward the left side in FIGS. 9A and 9B) in the X direction of the circuit board 200, as illustrated in FIG. 9B, the first bump 120a first comes into contact with the first protrusion portion 226a. The second bump 120b is not in contact with the second protrusion portion 226b.

When the first bump 120a comes into contact with the first protrusion portion 226a, the semiconductor chip 100 is started to be pressed onto the circuit board 200. When the semiconductor chip 100 is pressed onto the circuit board 200, a first reaction force Fla in parallel with the mounting surface of the circuit board 200 is applied from the first protrusion portion 226a to the first bump 120a. Thereby the semiconductor chip 100 moves toward the second board edge 210b of the circuit board 200 (toward the right side in FIGS. 9A and 9B) along with the first to the fourth bumps 120a to 120d. At this time, the first bump 120a moves toward the second board edge 210b of the circuit board 200 while sliding on the first protrusion portion 226a in the direction of arrow A.

As illustrated in FIG. 10A, when the second bump 120b comes into contact with the second protrusion portion 226b, a second reaction force Fib that offsets the first reaction force Fla is applied from the second protrusion portion 226b to the second bump 120b to stop the movement of the semiconductor chip 100. In other words, when the second bump 120b bumps into the second restriction surface 229b, the movement of the semiconductor chip 100 is restricted. In this way, the first and the second bumps 120a and 120b are accurately positioned in the longitudinal direction of the first and the second top surface electrodes 223a and 223b, that is, the X direction of the circuit board 200. When the first and the second bumps 120a to 120b are accurately positioned in the X direction of the circuit board 200, the semiconductor chip 100 is also accurately positioned in the X direction of the circuit board 200.

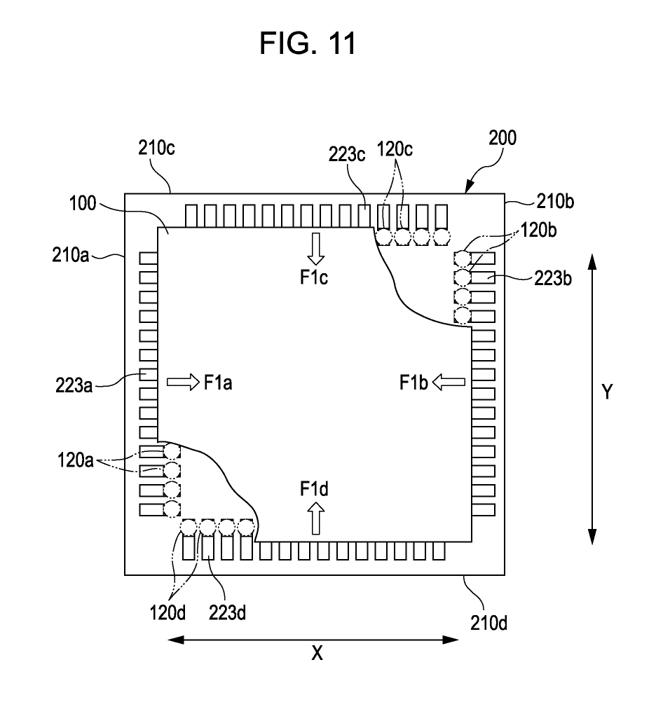

In this way, when the semiconductor chip 100 is accurately positioned in the X direction of the circuit board 200, as illustrated in FIG. 11, the third and the fourth bumps 120c and 120d are also accurately positioned in the X direction of the circuit board 200. Specifically, the third and the fourth bumps 120c and 120d are accurately positioned in the width direction of the third and the fourth top surface electrodes 223c and 223d, that is, the direction perpendicular to the longitudinal direction. Therefore, even if the width of the third and the fourth top surface electrodes 223c and 223d decreases as the electrode pitch of the semiconductor chip 100 becomes finer, it is possible to reliably mount the third and the fourth bumps 120c and 120d on the third and the fourth top surface electrodes 223c and 223d. Further, when the semiconductor chip 100 is started to be pressed, the central axes Oa and Ob of the first and the second bumps 120a and 120b only have to be arranged inside the first and the second restriction surfaces 229a and 229b. Thus the positioning operation is not difficult.

Although here, it is assumed that the semiconductor chip 100 is slightly shifted toward the first board edge 210a (toward the left side in FIGS. 9A and 9B) in the X direction of the circuit board 200, if the semiconductor chip 100 is slightly shifted toward the second board edge 210b in the X direction of the circuit board 200, the positioning operation can be performed in the same manner as described above.

When the semiconductor chip 100 is accurately positioned in the X direction of the circuit board 200, the semiconductor chip 100 is further pressed onto the circuit board 200. Then, the first and the second bumps 120a and 120b plastically flows into the inside of the first and the second protrusion portions 226a and 226b, and as illustrated in FIG. 10B, the first and the second bumps 120a and 120b are connected to the first and the second protrusion portions 226a and 226b and the first and the second mounting portions 227a and 227b. At this time, the first and the second bumps 120a and 120b are respectively held inside the first and the second protrusion portions 226a and 226b. In other words, the first and the second reaction forces F1a and F1b are respectively applied to the first and the second bumps 120a and 120b. Therefore, while the semiconductor chip 100 is being pressed onto the circuit board 200, the position of the semiconductor chip 100 is not shifted in the X direction of the circuit board 200. Therefore, in the process for mounting the semiconductor chip 100 on the circuit board 200, the third and the fourth bumps 120c and 120d do not drop out of the third and the fourth top surface electrodes 223c and 223d.

Although the cooperation between the first and the second bumps 120a and 120b and the first and the second top surface electrodes 223a and 223b has been focused and described, this is the same for the cooperation between the third and the fourth bumps 120c and 120d and the third and the fourth top surface electrodes 223c and 223d.

For example, if the semiconductor chip 100 is shifted toward the third board edge 210c in the Y direction of the circuit board 200, in the process for moving the semiconductor chip 100 toward the circuit board 200, the third bump 120c first comes into contact with the third protrusion portion 226c. When the semiconductor chip 100 is started to be pressed onto the circuit board 200, a third reaction force F1c in parallel with the mounting surface of the circuit board 200 is applied from the third protrusion portion 226c to the third bump 120c. Thereby the semiconductor chip 100 moves toward the fourth board edge 210d of the circuit board 200 along with the first to the fourth bumps 120a to 120d. Then, when the fourth bump 120d comes into contact with the fourth protrusion portion 226d, a fourth reaction force F1d that offsets the third reaction force F1c is applied from the fourth protrusion portion 226d to the fourth bump 120d to stop the movement of the semiconductor chip 100. In this way, the third and the fourth bumps 120c and 120d are accurately positioned in the longitudinal direction of the third and the fourth top surface electrodes 223c and 223d, that is, the Y direction of the circuit board 200. When the third and the fourth bumps 120c to 120d are accurately positioned in the Y direction of the circuit board 200, the semiconductor chip 100 is also accurately positioned in the Y direction of the circuit board 200.

In this way, when the semiconductor chip 100 is accurately positioned in the Y direction of the circuit board 200, as illustrated in FIG. 11, the first and the second bumps 120a and 120b of the semiconductor chip 100 are also accurately positioned in the Y direction of the circuit board 200. Specifically, the first and the second bumps 120a and 120b are accurately positioned in the width direction of the first and the second top surface electrodes 223a and 223b, that is, the direction perpendicular to the longitudinal direction. Therefore, even if the width of the first and the second top surface electrodes 223a and 223b decreases as the electrode pitch of the semiconductor chip 100 becomes finer, it is possible to reliably mount the first and the second bumps 120a and 120b on the first and the second top surface electrodes 223a and 223b. Further, when the semiconductor chip 100 is started to be pressed, the central axes Oc and Od of the third and the fourth bumps 120c and 120d only have to be arranged inside the third and the fourth restriction surfaces 229c and 229d. Thus the positioning operation is not difficult.

Although here, it is assumed that the semiconductor chip 100 is slightly shifted toward the third board edge 210c in the Y direction of the circuit board 200, if the semiconductor chip 100 is slightly shifted toward the fourth board edge 210d in the Y direction of the circuit board 200, the positioning operation can be performed in the same manner as described above.

When the semiconductor chip 100 is accurately positioned in the Y direction of the circuit board 200, the semiconductor chip 100 is further pressed onto the circuit board 200. Then, the third and the fourth bumps 120c and 120d plastically flows into the inside of the third and the fourth protrusion portions 226d and 226d, and the third and the fourth bumps 120c and 120d are connected to the third and the fourth protrusion portions 226c and 226d and the third and the fourth mounting portions 227c and 227d. At this time, the third and the fourth bumps 120c and 120d are respectively held inside the third and the fourth protrusion portions 226c and 226d. In other words, the third and the fourth reaction forces F1c and F1d are respectively applied to the third and the fourth bumps 120c and 120d. Therefore, while the semiconductor chip 100 is being pressed onto the circuit board 200, the position of the semiconductor chip 100 is not shifted in the Y direction of the circuit board 200. Therefore, in the process for mounting the semiconductor chip 100 on the circuit board 200, the first and the second bumps 120a and 120b do not drop out of the first and the second top surface electrodes 223a and 223b.

Although the positioning in the X direction and the positioning in the Y direction of the semiconductor chip 100 are separately described, the positioning in the X direction and the positioning in the Y direction of the semiconductor chip 100 progress simultaneously.

As described above, in the present embodiment, even when the semiconductor chip 100 is slightly shifted in the X direction or the Y direction of the circuit board 200, in the process for moving the semiconductor chip 100 closer to the circuit board 200, the position of the semiconductor chip 100 is gradually corrected and the semiconductor chip 100 is accurately positioned. Specifically, when the semiconductor chip 100 is moved closer to the circuit board 200, the first to the fourth bumps 120a to 120d automatically approach the correct positions thereof and the semiconductor chip 100 is accurately positioned. Further, the first to the fourth bumps 120a to 120d are held by the first to the fourth restriction surfaces 229a to 229d, so the semiconductor chip 100 does not shift in the process for pressing the semiconductor chip 100 onto the circuit board 200. As a result, the first to the fourth bumps 120a to 120d do not drop out of the first to the fourth top surface electrodes 223a to 223d.

According to the present embodiment, the semiconductor chip 100 can be accurately positioned by only forming the first to the fourth protrusion portions 226a to 226d on the first to the fourth pad portions 225a to 225d. Therefore, the first to the fourth top surface electrodes formed on the circuit board 200 need not be widened. Therefore, it is possible to make the electrode pitch of the semiconductor chip 100 much finer.

Although, in the present embodiment, all the first top surface electrodes 223a include the first protrusion portion 226a, the present embodiment is not limited to this. For example, at least one of the first top surface electrodes 223a only has to include the first protrusion portion 226a. This is the same for the second to the fourth top surface electrodes 223b to 223d.

### MODIFIED EXAMPLE

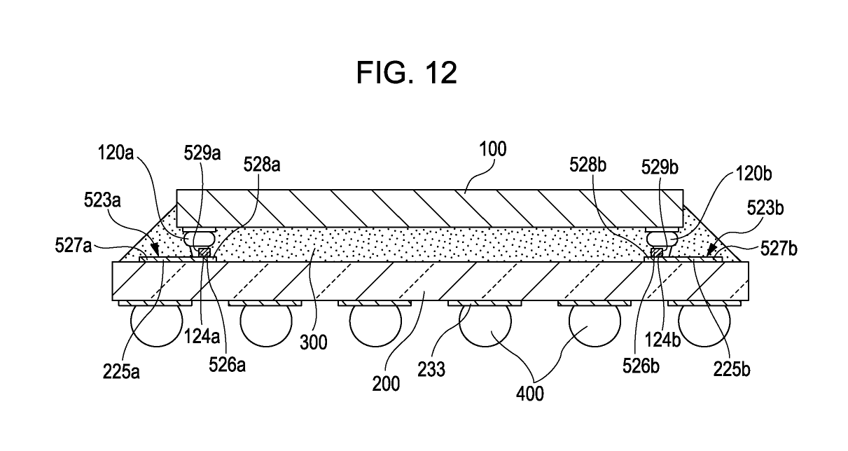

Hereinafter, a modified example of the first embodiment will be described with reference to FIGS. 12 to 14.

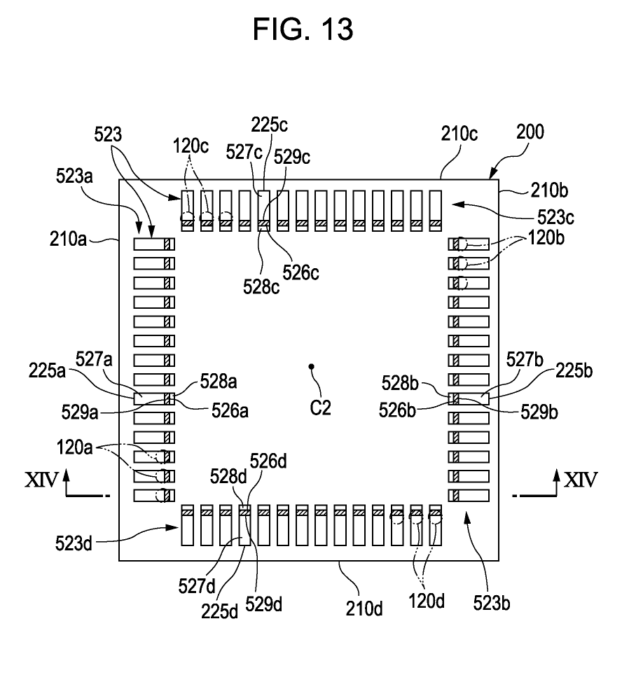

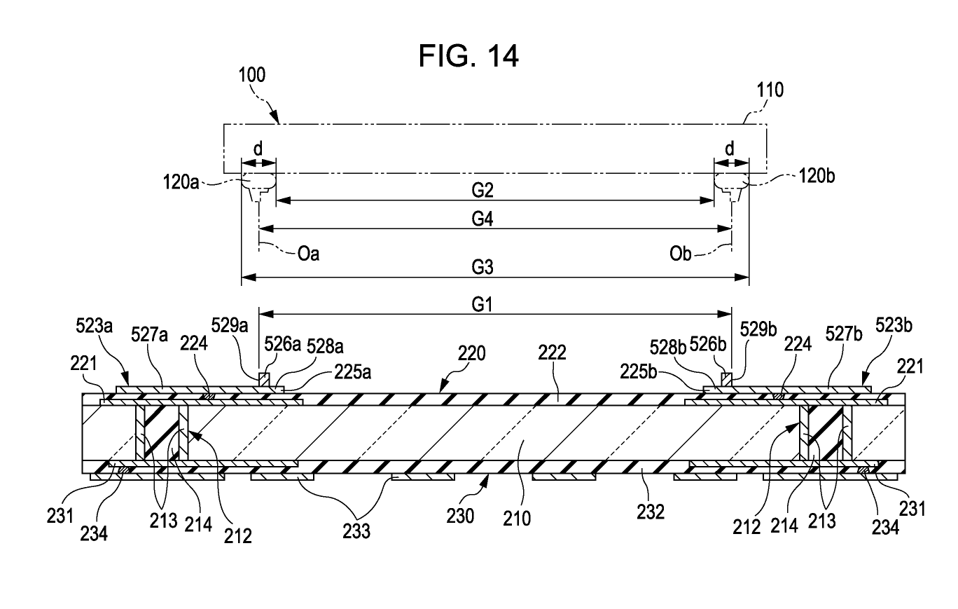

FIG. 12 is a cross-sectional view of a semiconductor device according to the modified example of the first embodiment and illustrates a cross-section corresponding to FIG. 2. FIG. 13 is a top view of the circuit board 200 according to the modified example of the first embodiment. FIG. 14 is a cross-sectional view of the circuit board 200 according to the modified example of the first embodiment and illustrates a cross-section taken along line XIV-XIV in FIG. 13. In FIG. 13, the first to the fourth bumps 120a to 120d are illustrated by virtual lines (two-dot chain lines). However, for clarification of the drawing, the number of the bumps illustrated in the drawing is limited to three for each of the first to the fourth bumps 120a to 120d.

First to fourth top surface electrodes 523a to 523d respectively include first to fourth protrusion portions 526a to 526d. Although the first to the fourth protrusion portions 526a to 526d are arranged on the first to the fourth pad portions 225a to 225d, the first to the fourth protrusion portions 526a to 526d are arranged inner than the first to the fourth protrusion portions 226a to 226d according to the first embodiment on the circuit board 200.

The first to the fourth protrusion portions 526a to 526d respectively define first to fourth mounting portions 527a to 527d and first to fourth extending portions 528a to 528d on the first to the fourth pad portions 225a to 225d. However, the first to the fourth mounting portions 527a to 527d are arranged on the side opposite to the first to the fourth mounting portions 227a to 227d according to the first embodiment, that is, on the outer side of the circuit board 200 with respect to the first to the fourth protrusion portions 526a to 526d. The extending portions 528a to 528d are arranged on the side opposite to the first to the fourth extending portions 228a to 228d according to the first embodiment, that is, on the inner side of the circuit board 200 with respect to the first to the fourth protrusion portions 526a to 526d.

The first to the fourth protrusion portions 526a to 526d respectively include first to fourth restriction surfaces 529a to 529d at portions facing the outside of the circuit board 200. The first to the fourth restriction surfaces 529a to 529d respectively extend in parallel with the first to the fourth board edges 210a to 210d, and restrict the first to the fourth bumps 120a to 120d of the semiconductor chip 100 from moving in a direction parallel with the mounting surface of the circuit board 200. Although the first to the fourth restriction surfaces 529a to 529d are formed on the first to the fourth protrusion portions 526a to 526d, the first to the fourth restriction surfaces 529a to 529d are located on the side opposite to the first to the fourth restriction surfaces 229a to 229d.

The first to the fourth protrusion portions 526a to 526d are arranged so that the distance between the first restriction surfaces 529a and the second restriction surfaces 529b is the same as the distance between the third restriction surfaces 529c and the fourth restriction surfaces 529d.

The first to the fourth bumps 120a to 120d of the semiconductor chip 100 are arranged to be mounted from the outer side to the inner side of the circuit board 200 with respect to the first to the fourth restriction surfaces 529a to 529d respectively, and connected to the first to the fourth mounting portions 527a to 527d and the first to the fourth protrusion portions 526a to 526d.

Therefore, the distance G1 between the first restriction surface 529a and the second restriction surface 529b is greater than the distance G2 between the first bump 120a and the second bump 120b, and smaller than the distance G3 obtained by adding two times the diameter d of the first and the second bumps 120a and 120b (=2d) to the distance G2 between the first bump 120a and the second bump 120b. Similarly, the distance G1 between the third restriction surface 529c and the fourth restriction surface 529d is greater than the distance G2 between the third bump 120c and the fourth bump 120d, and smaller than the distance G3 obtained by adding two times the diameter d of the third and the fourth bumps 120c and 120d (=2d) to the distance G2 between the third bump 120c and the fourth bump 120d.

Further, the first to the fourth bumps 120a to 120d are arranged so that the central axes Oa to Od thereof are located on the outer side of the circuit board 200 with respect to the first to the fourth regulation surfaces 529a to 529d respectively.

Therefore, the distance G1 between the first restriction surface 529a and the second restriction surface 529b is smaller than the distance G4 between the central axis Oa of the first bump 120a and the central axis Ob of the second bump 120b. Similarly, the distance G1 between the third restriction surface 529c and the fourth restriction surface 529d is smaller than the distance G4 between the central axis Oc of the third bump 120c and the central axis Od of the fourth axis 120d.

As described in the modified example, the first to the fourth restriction surfaces 529a to 529d may be respectively formed on the first to the fourth protrusion portions 526a to 526d at the portions facing the outside of the circuit board 200. When employing the modified example, if the semiconductor chip 100 is positioned so that the central axes Oa to Od of the first to the fourth bumps 120a to 120d are located on the outer side of the circuit board 200 with respect to the first to the fourth regulation surfaces 529a to 529d, and the semiconductor chip 100 is pressed onto the circuit board 200, the semiconductor chip 100 can be accurately positioned as described above. However, the first to the fourth regulation surfaces 529a to 529d are arranged to face a direction opposite to a direction faced by the first to the fourth regulation surfaces 229a to 229d according to the first embodiment, so the first to the fourth reaction forces according to the modified example are applied in directions opposite to the directions of the first to the fourth reaction forces according to the first embodiment.

### Second Embodiment

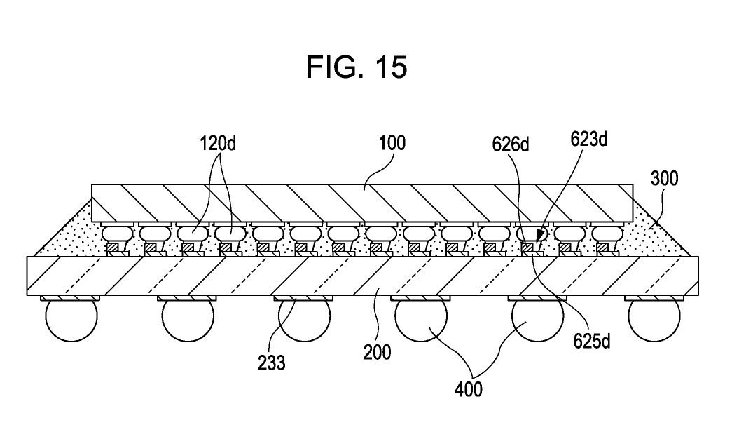

Hereinafter, a second embodiment will be described with reference to FIGS. 15 to 19. The same constituent elements as those in the first embodiment are given the same reference numerals and the descriptions thereof will be omitted.

Configuration of Semiconductor Device

First, a configuration of a semiconductor device will be described with reference to FIG. 15.

FIG. 15 is a cross-sectional view of the semiconductor device according to the second embodiment and illustrates a cross-section including the fourth bump 120d. That is, FIG. 15 illustrates the cross-section different from that of FIG. 2.

As illustrated in FIG. 15, the circuit board 200 according to the second embodiment includes first to fourth top surface electrodes 623a to 623d different from those in the first embodiment.

Configuration of Circuit Board

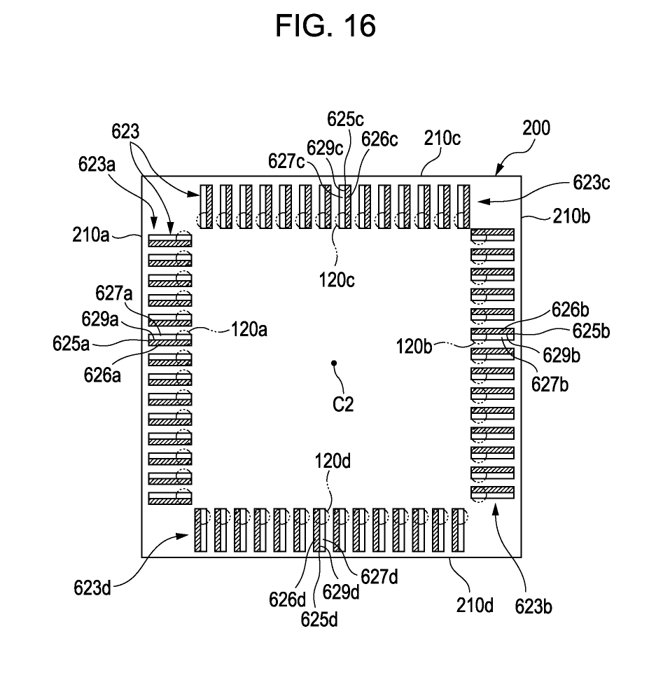

FIG. 16 is a top view of the circuit board 200 according to the second embodiment. As illustrated in FIG. 16, the first to the fourth top surface electrodes 623a to 623d according to the second embodiment respectively include first to fourth protrusion portions 626a to 626d. In FIG. 16, for clarification of the drawing, the first to the fourth protrusion portions 626a to 626d are shaded.

Although the first to the fourth protrusion portions 626a to 626d are arranged on first to fourth pad portions 625a to 625d, different from the first to the fourth pad portions 225a to 225d according to the first embodiment, the first to the fourth protrusion portions 626a to 626d are arranged along the longitudinal direction of the first to the fourth pad portions 625a to 625d.

The first to the fourth protrusion portions 626a to 626d respectively define first to fourth mounting portions 627a to 627d on the first to the fourth pad portions 625a to 625d. The width of the first to the fourth protrusion portions 626a to 626d, that is, the length in the direction perpendicular to the longitudinal direction is set to substantially a half of the width of the first to the fourth pad portions 625a to 625d, that is, substantially a half of the length in the direction perpendicular to the longitudinal direction.

The positions of the first to the fourth protrusion portions 626a to 626d on the first to the fourth pad portions 625a to 625d are different from each other for each of the first to the fourth pad portions 625a to 625d.

For example, the first protrusion portion 626a is located on the end portion of the first pad portion 625a facing the fourth board edge 210d, and a first restriction surface 629a is formed on a portion of the first protrusion portion 626a facing the third board edge 210c. The second protrusion portion 626b is located on the end portion of the second pad portion 625b facing the third board edge 210c, and a second restriction surface 629b is formed on a portion of the second protrusion portion 626b facing the fourth board edge 210d. The third protrusion portion 626c is located on the end portion of the third pad portion 625c facing the second board edge 210b, and a third restriction surface 629c is formed on a portion of the third protrusion portion 626c facing the first board edge 210a. The fourth protrusion portion 626d is located on the end portion of the fourth pad portion 625d facing the first board edge 210a, and a fourth restriction surface 629d is formed on a portion of the fourth protrusion portion 626d facing the second board edge 210b.

Although the first to the fourth restriction surfaces 629a to 629d face directions different from each other, all of them restrict the first to the fourth bumps 120a to 120d of the semiconductor chip 100 from moving in a direction parallel with the mounting surface of the circuit board 200.

The first and the second top surface electrodes 623a and 623b are arranged so that the first restriction surface 629a is located nearer to the fourth board edge 210d than the second restriction surface 629b. Therefore, the distance between the first top surface electrode 623a according to the present embodiment and the fourth board edge 210d (or the third board edge 210c) of the circuit board 200 is not the same as the distance between the second top surface electrode 623b according to the present embodiment and the fourth board edge 210d (or the third board edge 210c) of the circuit board 200. The third and the fourth top surface electrodes 623c and 623d are arranged so that the third restriction surface 629c is located nearer to the second board edge 210b than the fourth restriction surface 629d. Therefore, the distance between the third top surface electrode 623c and the second board edge 210b (or the first board edge 210a) of the circuit board 200 is not the same as the distance between the fourth top surface electrode 623d and the second board edge 210b (or the first board edge 210a) of the circuit board 200. By arranging the first to the fourth top surface electrodes 623a to 623d as described above, when the semiconductor chip 100 is moved closer to the circuit board 200, the first to the fourth bumps 120a to 120d can come into contact with the first to the fourth restriction surfaces 629a to 629d.

Positioning Process of Semiconductor Chip

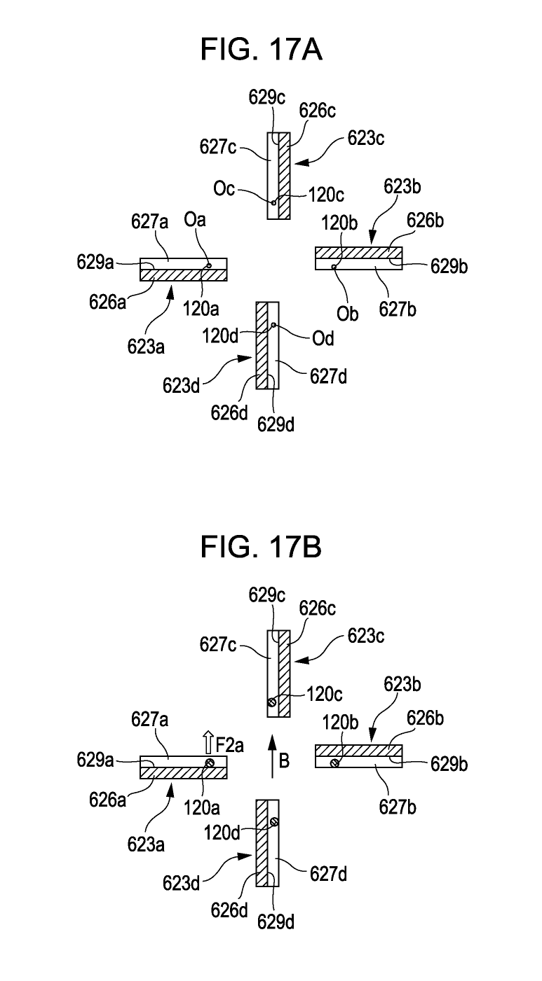

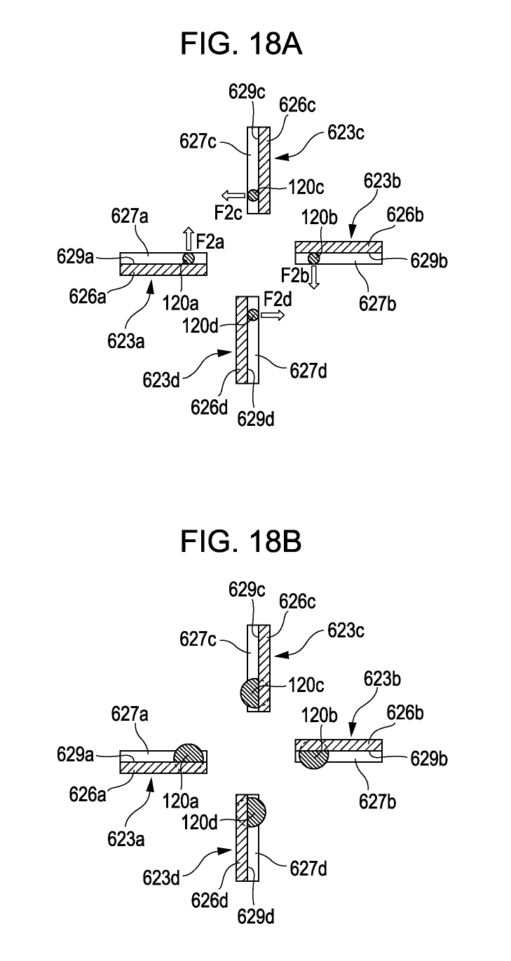

Next, the positioning process of the semiconductor chip 100 will be described with reference to FIGS. 17A, 17B, 18A, and 18B.

FIGS. 17A, 17B, 18A, and 18B are illustrations for explaining a positioning process of the semiconductor chip 100 according to the second embodiment. Reference numerals 120a to 120c in FIGS. 17A, 17B, 18A, and 18B denote cross-sections of the first to the fourth bumps 120a to 120d instead of external shapes of the first to the fourth bumps 120a to 120d. Here, the first to the fourth bumps 120a to 120d are cross-sectioned by a plane including the top surfaces of the first to fourth protrusion portions 626a to 626d.

First, the pressure head H that absorbs the semiconductor chip 100 is driven to position the semiconductor chip 100 so that the central axes Oa to Od of the first to the fourth bumps 120a to 120d are respectively located on the first to the fourth mounting portions 627a to 627d as illustrated in FIG. 17A. Then, the pressure head H is lowered and the semiconductor chip 100 is moved closer to the circuit board 200. The semiconductor chip 100 and the pressure head H are not illustrated in FIGS. 17A, 17B, 18A, and 18B.

At this time, if the semiconductor chip 100 is shifted toward the fourth board edge 210d (toward the bottom in FIGS. 17A and 17B), as illustrated in FIG. 17B, the first bump 120a first comes into contact with the first protrusion portion 626a. The second to the fourth bumps 120b to 120d are not in contact with the second to the fourth protrusion portions 626b to 626d.

When the first bump 120a comes into contact with the first protrusion portion 626a, the pressure head H starts pressing the semiconductor chip 100 onto the circuit board 200. When the semiconductor chip 100 is pressed onto the circuit board 200, a first reaction force F2a in parallel with the mounting surface of the circuit board 200 is applied from the first protrusion portion 626a to the first bump 120a. Thereby the semiconductor chip 100 moves in the direction of arrow B along with the first to the fourth bumps 120a to 120d.

At this time, if the semiconductor chip 100 does not rotate but moves, as illustrated in FIG. 18A, the second to the fourth bumps 120b to 120d come into contact with the second to the fourth protrusion portions 626b to 626d at substantially the same time.

When the second bump 120b comes into contact with the second protrusion portion 626b, a second reaction force F2b that offsets the first reaction force F2a is applied from the second protrusion portion 626b to the second bump 120b to stop the movement of the semiconductor chip 100. When the third and the fourth bumps 120c and 120d respectively come into contact with the third and the fourth protrusion portions 626c and 626d, a third and a fourth reaction forces F2c and F2d, which are in parallel with the mounting surface of the circuit board 200 and offset each other, are respectively applied from the third and the fourth protrusion portions 626c and 626d to the third and the fourth bump 120c and 120d. The third and the fourth reaction forces F2c and F2d offset rotation moment due to the first and the second reaction forces F2a and F2b, so the semiconductor chip 100 is not rotated by the first to the fourth reaction forces F2a and F2d. In this way, when the first to the fourth bumps 120a to 120d come into contact with the first to the fourth protrusion portions 626a to 626d, the movement and the rotation of the first to the fourth bumps 120a to 120d are restricted and the semiconductor chip 100 comes to rest. In this way, the first to the fourth bumps 120a to 120d are accurately positioned with respect to the first to the fourth top surface electrodes 623a to 623d. When the first to the fourth bumps 120a to 120d are accurately positioned, the semiconductor chip 100 is also accurately positioned with respect to the circuit board 200.

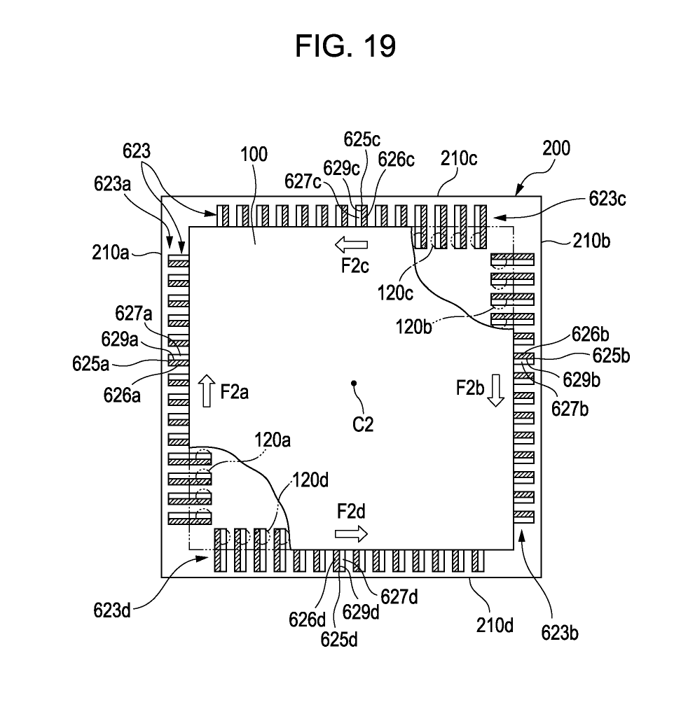

Although a case in which the semiconductor chip 100 moves without rotating has been described, the semiconductor chip 100 may move while rotating depending on the absorption force and the static friction coefficient of the pressure head H. For example, as illustrated in FIG. 17B, when the first reaction force F2a is applied from the first protrusion portion 626a to the first bump 120a, the semiconductor chip 100 may rotate in the clockwise direction. In this case, before the second bump 120b comes into contact with the second protrusion portion 626b, the third and the fourth bumps 120c and 120d come into contact with the third and the fourth protrusion portions 626c and 626d. Thereby the third and the fourth reaction forces F2c and F2d which offset each other are applied from the third and the fourth protrusion portions 626c and 626d to the third and the fourth bumps 120c and 120d, and the rotation of the semiconductor chip 100 is stopped. In other words, when the third and the fourth bumps 120c and 120d come into contact with the third and the fourth protrusion portions 626c and 626d, the third and the fourth reaction forces F2c and F2d are applied to offset the rotation moment due to the first reaction force F2a, so that the rotation of the semiconductor chip 100 is restricted. Then, the semiconductor chip 100 moves in the direction of arrow B along with the first to the fourth bumps 120a to 120d owing to the first reaction force F2a. Then, when the second bump 120b comes into contact with the second protrusion portion 626b, a second reaction force F2b that offsets the first reaction force F2a is applied from the second protrusion portion 626b to the second bump 120b to stop the movement of the semiconductor chip 100. In this way, when the first to the fourth bumps 120a to 120d come into contact with the first to the fourth restriction surfaces 629a to 629d, the movement and the rotation of the semiconductor chip 100 are restricted and the semiconductor chip 100 comes to rest. In this way, the first to the fourth bumps 120a to 120d are accurately positioned with respect to the first to the fourth top surface electrodes 623a to 623d. When the first to the fourth bumps 120a to 120d are positioned, as illustrated in FIG. 19, the semiconductor chip 100 is also accurately positioned with respect to the circuit board 200.

Therefore, even if the width of the first to the fourth top surface electrodes 623a to 623d decreases as the electrode pitch of the semiconductor chip 100 becomes finer, it is possible to accurately position the first to the fourth bumps 120a to 120d with respect to the first to the fourth top surface electrodes 623a and 623d. Further, when the semiconductor chip 100 is started to be pressed, the central axes Oa to Od of the first to the fourth bumps 120a to 120d only have to be arranged on the first to the fourth mounting portions 627a to 627d. Thus the positioning operation is not difficult.

When the semiconductor chip 100 is accurately positioned, the semiconductor chip 100 is further pressed onto the circuit board 200. Then, the first to the fourth bumps 120a to 120d plastically flows from the first to the fourth protrusion portions 626a to 626d to the first to the fourth mounting portions 627a to 627d, and as illustrated in FIG. 18B, the first to the fourth bumps 120a to 120d are respectively connected to the first to the fourth protrusion portions 626a to 626b and the first to the fourth mounting portions 627a to 627d. At this time, the first to the fourth bumps 120a to 120d are respectively held by the first to the fourth protrusion portions 626a to 626d. In other words, the first to the fourth reaction forces Fla to F2d are respectively applied to the first to the fourth bumps 120a to 120d. Therefore, while the semiconductor chip 100 is being pressed onto the circuit board 200, the position of the semiconductor chip 100 is not shifted in the X direction or the Y direction of the circuit board 200. As a result, the first to the fourth bumps 120a to 120d do not drop out of the first to the fourth top surface electrodes 623a to 623d.

As described above, in the present embodiment, even when the semiconductor chip 100 is slightly shifted with respect to the circuit board 200, in the process for moving the semiconductor chip 100 closer to the circuit board 200, the positions of the first to the fourth bumps 120a to 120d are gradually corrected and the semiconductor chip 100 is accurately positioned. Specifically, when the semiconductor chip 100 is moved closer to the circuit board 200, the first to the fourth bumps 120a to 120d automatically approach the correct positions thereof and the semiconductor chip 100 is accurately positioned. Further, the first to the fourth bumps 120a to 120d are held by the first to the fourth restriction surfaces 629a to 629d, so the semiconductor chip 100 does not shift in the process for pressing the semiconductor chip 100 onto the circuit board 200. As a result, the first to the fourth bumps 120a to 120d do not drop out of the first to the fourth top surface electrodes 623a to 623d.

According to the present embodiment, the semiconductor chip 100 can be accurately positioned by only forming the first to the fourth protrusion portions 626a to 626d on the first to the fourth pad portions 625a to 625d. Therefore, the first to the fourth top surface electrodes formed on the circuit board 200 need not be widened. Therefore, it is possible to make the electrode pitch of the semiconductor chip 100 much finer.

In the present embodiment, all the first top surface electrodes 623a include the first protrusion portion 626a. However the present embodiment is not limited to this. For example, at least one of the first top surface electrodes 623a only has to include the first protrusion portion 626a. This is the same for the second to the fourth top surface electrodes 623b to 623d.

In the present embodiment, the first top surface electrode 623a is located nearer to the fourth board edge 210d than the second top surface electrode 623b. However the present embodiment is not limited to this. If the first restriction surface 629a is located nearer to the fourth board edge 210d than the second restriction surface 629b, the locations and the shapes of the first and the second top surface electrodes 623a and 623b are not particularly limited. For example, it is possible to locate the first and the second top surface electrodes 623a and 623b at the same distance from the fourth board edge 210d and set the width of the first and the second protrusion portions 626a and 626b smaller than one half of the width of the first and the second pad portions 625a and 625b. In this way, the first restriction surface 629a can also be located nearer to the fourth board edge 210d than the second restriction surface 629b. This is the same for the third and the fourth top surface electrodes 623c to 623d.

### Modified Example 1

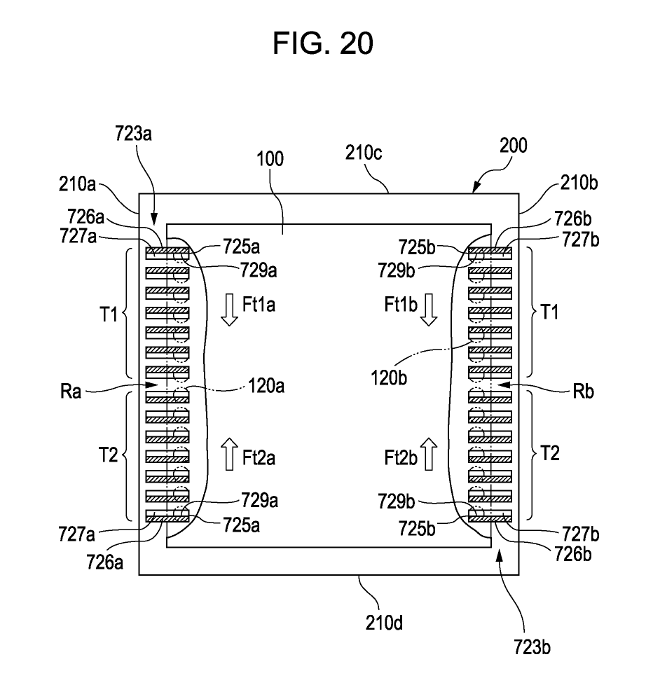

Hereinafter, a modified example 1 of the second embodiment will be described with reference to FIG. 20.

FIG. 20 is an illustration for explaining positioning of the semiconductor chip 100 according to the modified example 1 of the second embodiment.

Assuming that the semiconductor chip 100 do not include the third and the fourth bumps 120c and 120d, as illustrated in FIG. 20, the circuit board 200 according to the present modified example includes only first and second top surface electrodes 723a and 723b corresponding to the first and the second bumps 120a and 120b. The first and the second top surface electrodes 723a and 723b are classified into a first type T1 and a second type T2 according to the positions of first and second protrusion portions 726a and 726b on first and second pad portions 725a and 725b. In FIG. 20, for clarification of the drawing, the first and the second protrusion portions 726a and 726b are shaded.

The numbers and the pitches of the first top surface electrodes 723a included in the first type T1 and the first top surface electrodes 723a included in the second type T2 are the same. In the same manner, the numbers and the pitches of the second top surface electrodes 723b included in the first type T1 and the second top surface electrodes 723b included in the second type T2 are the same.

In the first type T1, the first and the second protrusion portions 726a and 726b are respectively provided on the end portions of the first and the second pad portions 725a and 725b facing the third board edge 210c, and first and second restriction surfaces 729a and 729b are formed on surfaces of the first and the second protrusion portions 726a and 726b facing the fourth board edge 210d. The first and the second protrusion portions 726a and 726b according to the first type T1 respectively define first and second mounting portions 727a and 727b in an area nearer to the fourth board edge 210d on the first and the second pad portions 725a and 725b.

In the second type T2, the first and the second protrusion portions 726a and 726b are respectively provided on the end portions of the first and second pad portions 725a and 725b facing the fourth board edge 210d, and the first and the second restriction surfaces 729a and 729b are formed on surfaces of the first and the second protrusion portions 726a and 726b facing the third board edge 210c. The first and the second protrusion portions 726a and 726b according to the second type T2 respectively define the first and the second mounting portions 727a and 727b in an area nearer to the third board edge 210c on the first and the second pad portions 725a and 725b.

As a result, the first restriction surface 729a of the first type T1 faces a direction opposite to that faced by the first restriction surface 729a of the second type T2. In the same manner, the second restriction surface 729b of the first type T1 faces a direction opposite to that faced by the second restriction surface 729b of the second type T2. The position of the first mounting portion 727a of the first type T1 is opposite to the position of the first mounting portion 727a of the second type T2. In the same manner, the position of the second mounting portion 727b of the first type T1 is opposite to the position of the second mounting portion 727b of the second type T2.

At boundary portions between the first type T1 and the second type T2 of the first top surface electrodes 723a and the second top surface electrodes 723b, there are gaps larger than the pitches of the electrodes, that is, sections Ra and Rb in which no top surface electrode is formed. By arranging the first and the second top surface electrodes 723a and 723b as described above, when the semiconductor chip 100 is moved closer to the circuit board 200, the central axes Oa and Ob of the first and the second bumps 120a and 120b are respectively arranged on the first and the second mounting portions 727a and 727b and the first and the second bumps 120a and 120b can respectively come into contact with the first and the second restriction surfaces 729a and 729b.

When employing the present modified example, if the semiconductor chip 100 is positioned so that the central axes Oa and Ob of the first and the second bumps 120a and 120b are located on the first and the second mounting portions 727a and 727b of the circuit board 200, and the semiconductor chip 100 is pressed onto the circuit board 200, the semiconductor chip 100 can be accurately positioned as described above.

However, the first and the second top surface electrodes 723a and 723b according to the present modified example are different from those in the second embodiment, so the reaction forces applied to the first and the second bumps 120a and 120b when the semiconductor chip 100 is pressed onto the circuit board 200 are different from the first and the second reaction forces F1a and F2b according to the second embodiment.

For example, when the semiconductor chip 100 is pressed onto the circuit board 200, in the first type T1, a first reaction force Ft1a in parallel with the mounting surface of the circuit board 200 is applied from the first protrusion portions 726a of the first top surface electrodes 723a to the first bumps 120a. A third reaction force Ft1b in parallel with the mounting surface of the circuit board 200 is applied from the second protrusion portions 726b of the second top surface electrodes 723b to the second bumps 120a. In the second type T2, a second reaction force Ft2a that offsets the first reaction force Ft1a is applied from the first protrusion portions 726a of the first top surface electrodes 723a to the first bumps 120a. A fourth reaction force Ft2b that offsets the third reaction force Ft1b is applied from the second protrusion portions 726b of the second top surface electrodes 723b to the second bumps 120a.

Although the present modified example assumes that the semiconductor chip 100 does not include the third and the fourth bumps 120c and 120d, it is not limited to this. For example, the semiconductor chip 100 may include the first to the fourth bumps 120a to 120d. In this case, the shapes of the third and the fourth top surface electrodes (not illustrated in FIG. 20) for connecting with the third and the fourth bumps 120c and 120d are not particularly limited. However, top surface electrodes (not illustrated in FIG. 20) corresponding to the first and the second top surface electrodes 723a and 723b according to the present modified example may be arranged along the third and the fourth board edges 210c and 210d of the circuit board 200 to be used as the third and the fourth top surface electrodes.

### Modified Example 2

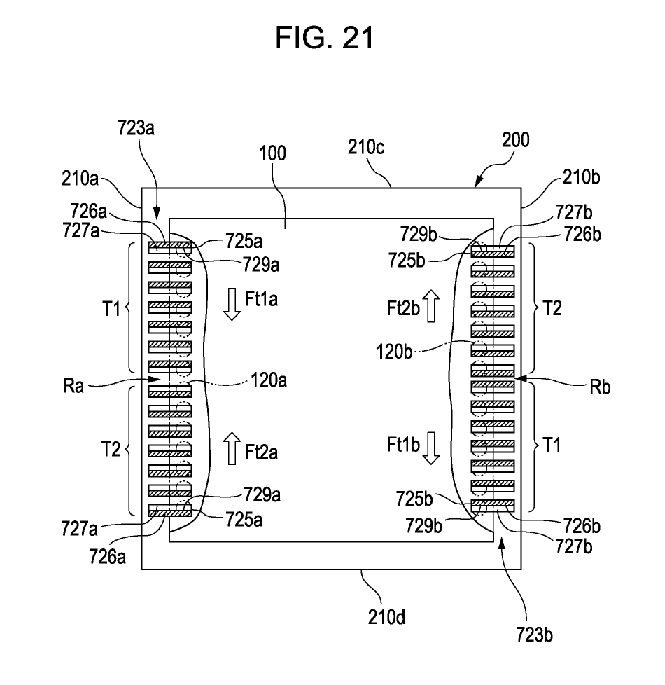

Hereinafter, a modified example 2 of the second embodiment will be described with reference to FIG. 21.

FIG. 21 is an illustration for explaining positioning of the semiconductor chip 100 according to the modified example 2 of the second embodiment.

As illustrated in FIG. 21, the positions of the first type T1 and the second type T2 of the second top surface electrodes 723b according to the present modified example are opposite to those of the modified example 1 of the second embodiment. Even if the positions of the first type T1 and the second type T2 are reversed as illustrated in the present modified example, the semiconductor chip 100 can be accurately positioned in the same manner as in the modified example 1. However, as the positions of the first type T1 and the second type T2 are reversed, the section Rb which is formed on a boundary portion between the first type T1 and the second type T2 and in which the second top surface electrode 723b is not formed is smaller than the pitch of the second top surface electrodes 723b.

Although, in the present modified example, the positions of the first type T1 and the second type T2 of the second top surface electrodes 723b are reversed from those in the modified example 1, it is not limited to this, but the positions of the first type T1 and the second type T2 of either or both of the first and the second top surface electrodes 723a and 723b may be reversed from those in the modified example 1.

### Third Embodiment

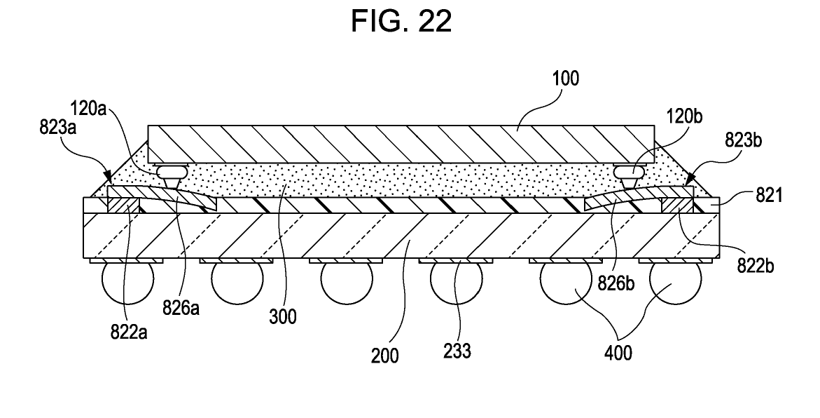

Hereinafter, a third embodiment will be described with reference to FIGS. 22 to 28C. The same constituent elements as those in the first and the second embodiments are given the same reference numerals and the descriptions thereof will be omitted.

Configuration of Semiconductor Device

First, a configuration of a semiconductor device will be described with reference to FIGS. 22 to 24.

FIG. 22 is a cross-sectional view of the semiconductor device according to the third embodiment and illustrates a cross-section corresponding to FIG. 2. As illustrated in FIG. 22, the circuit board 200 according to the third embodiment includes first to fourth top surface electrodes 823a to 823d different from those in the first embodiment. Further, the circuit board 200 according to the third embodiment includes a deformation absorption film 821.

Configuration of Circuit Board

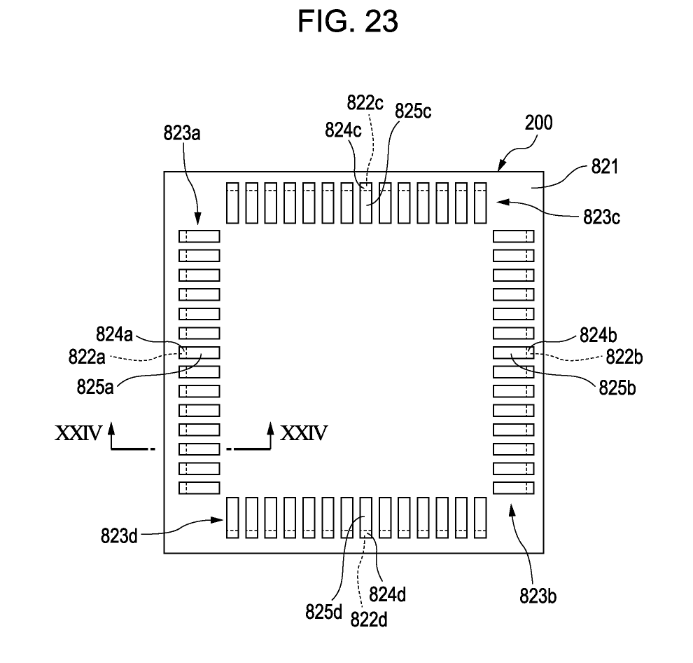

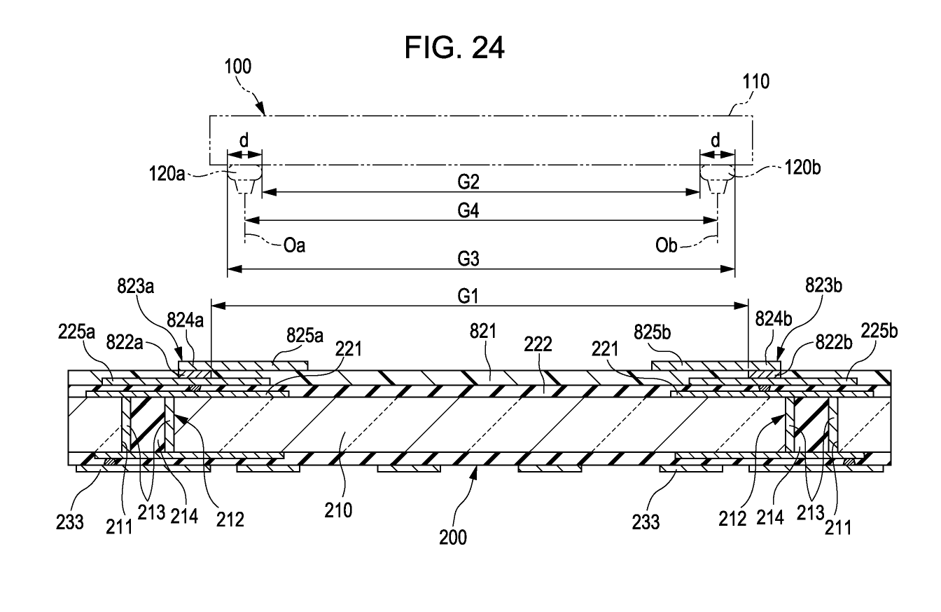

FIG. 23 is a top view of the circuit board 200 according to the third embodiment. FIG. 24 is a cross-sectional view of the circuit board 200 according to the third embodiment and illustrates a cross-section taken along line XXIV-XXIV in FIG. 23.

As illustrated in FIGS. 23 and 24, the circuit board 200 according to the third embodiment includes the first to the fourth pad portions 225a to 225d according to the first embodiment, but does not include the first to the fourth protrusion portions 226a to 226d. The circuit board 200 according to the third embodiment uses the first to the fourth pad portions 225a to 225d according to the first embodiment as first to fourth internal wiring patterns 225a to 225d.

Further, the circuit board 200 according to the third embodiment includes the deformation absorption film 821 that covers the first to the fourth internal wiring patterns 225a to 225d and the top surface insulating film 222. As a material of the deformation absorption film 821, a material having rigidity lower than that of the first to the fourth internal wiring patterns 225a to 225d and the top surface insulating film 222, for example, an epoxy resin or a phenol resin is used. The film thickness of the deformation absorption film 821 is, for example, about 20 μm to 40 μm.

The deformation absorption film 821 is formed on the first to the fourth internal wiring patterns 225a to 225d and the top surface insulating film 222, and first to fourth post portions 822a to 822d are respectively buried at positions corresponding to the first to the fourth internal wiring patterns 225a to 225d. The first to the fourth post portions 822a to 822d are formed over the entire width of the first to the fourth internal wiring patterns 225a to 225d and respectively connected to the first to the fourth internal wiring patterns 225a to 225d. As a material of the first to the fourth post portions 822a to 822d, an electrically conductive material having rigidity higher than that of the deformation absorption film 821, for example, a metal such as Cu is used. The film thickness of the first to the fourth post portions 822a to 822d is substantially the same as the film thickness of the deformation absorption film 821.

The first to the fourth top surface electrodes 823a to 823d according to the third embodiment are arranged corresponding to the first to the fourth internal wiring patterns 225a to 225d, and respectively include first to fourth fixed portions 824a to 824d and first to fourth flexible beam portions 825a to 825d.

The first to the fourth fixed portions 824a to 824d are respectively arranged on the first to the fourth post portions 822a to 822d and electrically connected to the first to the fourth post portions 822a to 822d. The first to the fourth flexible beam portions 825a to 825d are respectively arranged on the deformation absorption film 821, and bend closer to the core member 210 as the distance from the first to the fourth post portions 822a to 822d of the circuit board 200 increases.

The first to the fourth bumps 120a to 120d of the semiconductor chip 100 are respectively connected to the first to the fourth flexible beam portions 825a to 825d. Therefore, the distance G1 between the first post portion 822a and the second post portion 822b is set to be greater than the distance G4 between the central axis Oa of the first bump 120a and the central axis Ob of the second bump 120b. More preferably, the distance G1 between the first post portion 822a and the second post portion 822b is set to be greater than the distance G3 obtained by adding two times the diameter d of the first and the second bumps 120a and 120b (=2d) to the distance G2 between the first bump 120a and the second bump 120b. When employing the above distances, the entire portions of the first and the second bumps 120a and 120b can be connected to the first and the second flexible beam portions 825a and 825b. Specifically, the semiconductor chip 100 can be positioned so that the first and the second bumps 120a and 120b are not connected to the first and the second fixed portions 824a and 824b. Similarly, the distance G1 between the third post portion 822c and the fourth post portion 822d is set to be greater than the distance G4 between the central axis Oc of the third bump 120c and the central axis Od of the fourth bump 120d. More preferably, the distance G1 between the third post portion 822c and the fourth post portion 822d is set to be greater than the distance G3 obtained by adding two times the diameter d of the third and the fourth bumps 120c and 120d (=2d) to the distance G2 between the third bump 120c and the fourth bump 120d. When employing the above distances, the entire portions of the third and the fourth bumps 120c and 120d can be connected to the third and the fourth flexible beam portions 825c and 825d. Specifically, the semiconductor chip 100 can be positioned so that the third and the fourth bumps 120c and 120d are not connected to the third and the fourth fixed portions 824c and 824d.

Manufacturing Method of Circuit Board

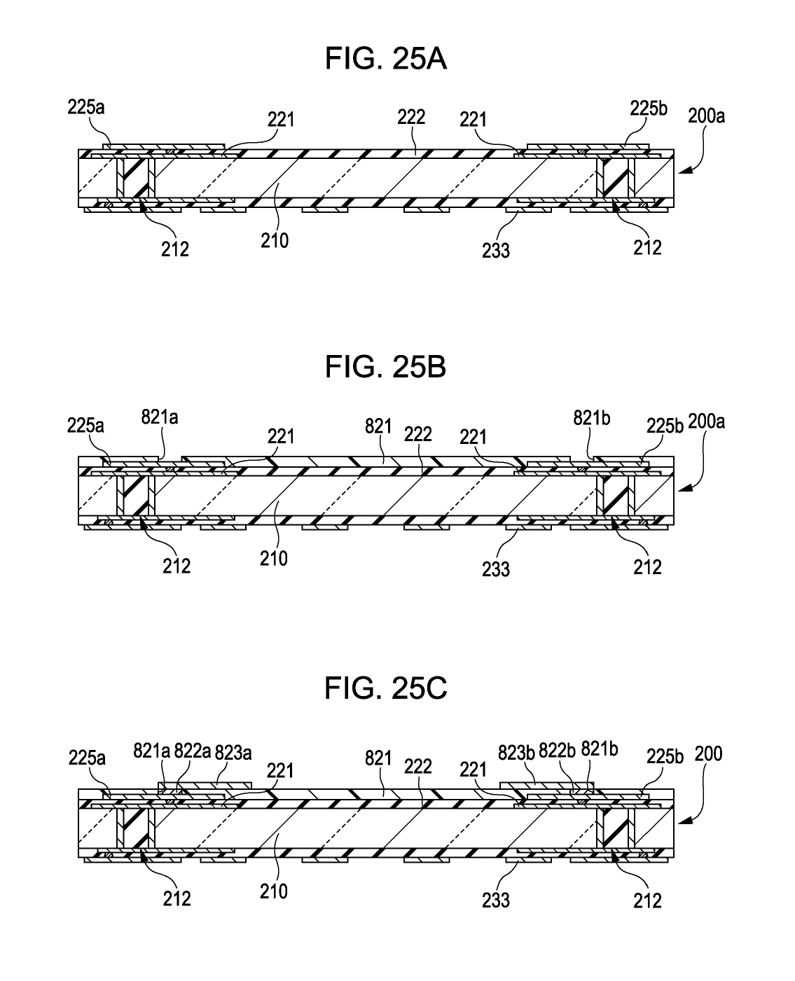

Next, a manufacturing method of the circuit board will be described with reference to FIGS. 25A to 25C.

FIGS. 25A to 25C are illustrations for explaining a manufacturing method of the circuit board 200 according to the third embodiment.

First, as illustrated in FIG. 25A, a so-called glass epoxy board 200a is prepared. The glass epoxy board 200a is a board in which the first to the fourth protrusion portions 226a to 226d are removed from the circuit board 200 according to the first embodiment and the first to the fourth pad portions 225a to 225d which are used as the first to the fourth internal wiring patterns 225a to 225d according to the present embodiment are remained.

Next, as illustrated in FIG. 25B, the deformation absorption film 821 is formed on the glass epoxy board 200a. As a forming method of the deformation absorption film 821, for example, a screen printing method or a spin coat method may be used. The film thickness of the deformation absorption film 821 is, for example, 20 μm to 40 μm. Openings 821a are formed at positions corresponding to the first to the fourth internal wiring patterns 225a to 225d in the deformation absorption film 821. As a method for forming the openings 821a, for example, laser processing or an etching method is used. When the laser processing is employed, the first to the fourth internal wiring patterns 225a to 225d may be a processing stop surface. When the etching method is employed, an etchant corresponding to the material of the deformation absorption film 821 may be used. For example, if the material of the deformation absorption film 821 is an epoxy resin, for example, concentrated sulfuric acid, chromic acid, alkaline permanganate, or the like may be used as an etchant. After the deformation absorption film 821 is formed, for example, CMP (Chemical Mechanical Polishing) may be performed to planarize the surface of the deformation absorption film 821.

Next, as illustrated in FIG. 25C, a shield layer (not illustrated in the drawings) of, for example, Cu or the like is formed on the deformation absorption film 821, and by using the shield layer as a power feeding layer, a metal film (not illustrated in the drawings) of, for example, Cu or the like is formed by electroplating. At this time, the metal film is buried in the openings 821a formed in the deformation absorption film 821 to form the first to the fourth post portions 822a to 822d. Then, unnecessary portions of the metal film are removed by, for example, CMP (Chemical Mechanical Polishing) to planarize the surface of the metal film. Thereafter, a resist pattern (not illustrated in the drawings) is formed on the metal film, and the metal film is etched by using the resist pattern as a mask. Thereby the first to the fourth top surface electrodes 823a to 823d are formed.

In this way, the circuit board 200 according to the third embodiment is completed. As described above, the circuit board 200 can be easily manufactured by only performing film formation and etching on a glass epoxy board used in ordinary semiconductor devices.

Manufacturing Method of Semiconductor Device

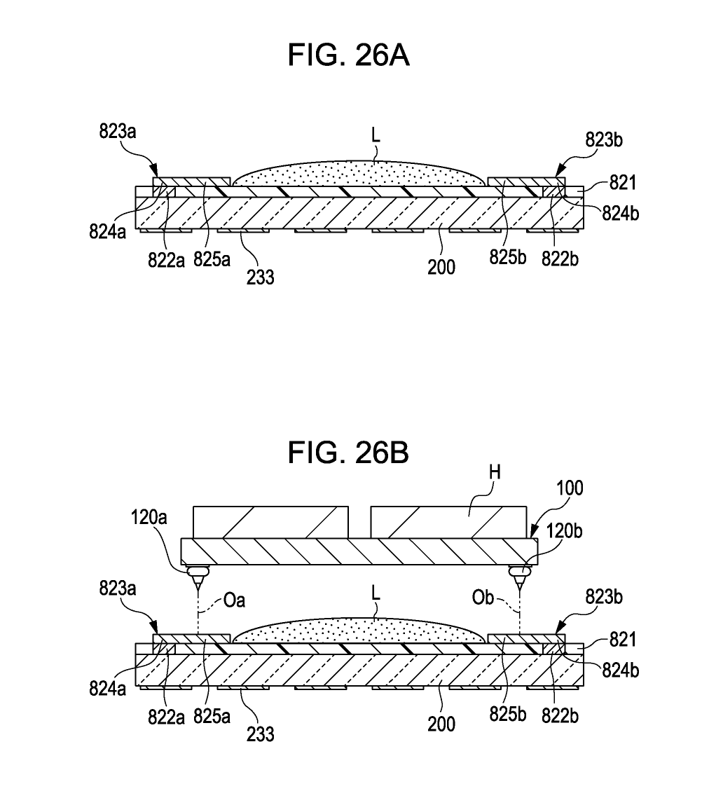

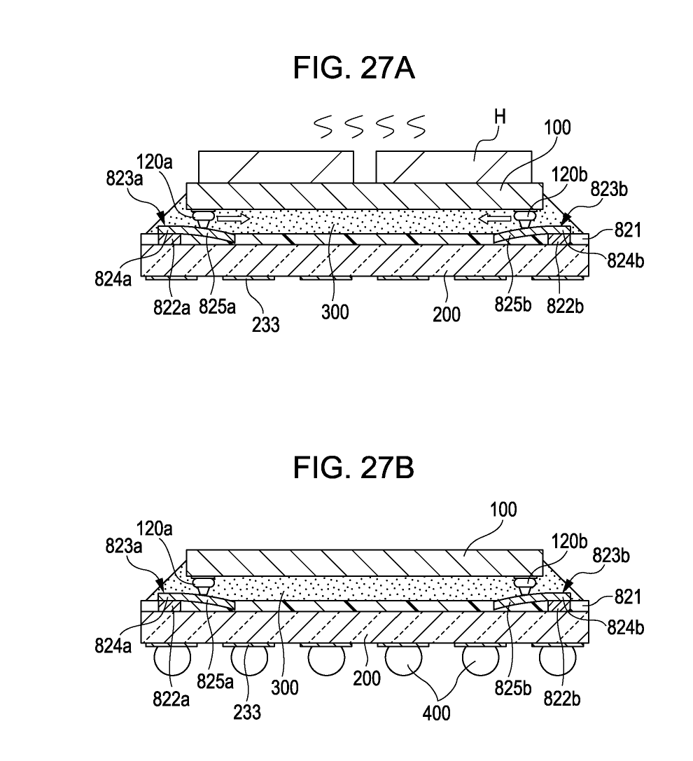

Next, a manufacturing method of the semiconductor device will be described with reference to FIGS. 26A, 26B, 27A, and 27B.

FIGS. 26A, 26B, 27A, and 27B are illustrations for explaining the manufacturing method of the semiconductor device according to the third embodiment.

First, as illustrated in FIG. 26A, an epoxy system resin L is provided to the top surface of the circuit board 200 by, for example, a dispense method. The epoxy system resin L is, for example, a material in which fillers made of silica is added to an epoxy resin.

Next, as illustrated in FIG. 26B, the semiconductor chip 100 is absorbed to the bottom surface of the pressure head H, and the semiconductor chip 100 is positioned so that the central axes Oa to Od of the first to the fourth bumps 120a to 120d are respectively located over the first to the fourth flexible beam portions 825a to 825d. At this time, the first to the fourth bumps 120a to 120d are formed into a conical shape in which the diameter thereof decreases as the distance from the chip main body 110 increases. In other words, the first to the fourth bumps 120a to 120d respectively have a sharp top end portion.

Next, as illustrated in FIG. 27A, the pressure head H that absorbs the semiconductor chip 100 is lowered and the semiconductor chip 100 is moved closer to the circuit board 200. Thereby the epoxy system resin L provided on the circuit board 200 is pressed and spread by the semiconductor chip 100 and the gap between the semiconductor chip 100 and the circuit board 200 is filled.

When the first to the fourth bumps 120a to 120d come into contact with the first to the fourth flexible beam portions 825a to 825d, the semiconductor chip 100 is started to be pressed onto the circuit board 200. Then, the first to the fourth flexible beam portions 825a to 825d are pressed by the first to the fourth bumps 120a to 120d and bend closer to the core member 210. Thereby the first to the fourth bumps 120a to 120d are accurately positioned with respect to the first to the fourth top surface electrodes 823a to 823d through a positioning process described below. When the first to the fourth bumps 120a to 120d are accurately positioned, the semiconductor chip 100 is also accurately positioned with respect to the circuit board 200.

Then, the semiconductor chip 100 is further pressed to respectively connect the first to the fourth bumps 120a to 120d to the first to the fourth flexible beam portions 825a to 825d. At this time, the first to the fourth bumps 120a to 120d are deformed according to the shapes of the first to the fourth flexible beam portions 825a to 825d. Thereby the sharp top end portions of the first to the fourth bumps 120a to 120d are flattened.

When the first to the fourth bumps 120a to 120d are respectively connected to the first to the fourth flexible beam portions 825a to 825d, while the semiconductor chip 100 is still pressed onto the circuit board 200, the semiconductor chip 100 is heated by a heater (not illustrated in the drawings) provided in the pressure head H to solidify the epoxy system resin L in the gap between the semiconductor chip 100 and the circuit board 200. Thereby the epoxy system resin L contracts, and the semiconductor chip 100 and the circuit board 200 are bonded together. As described above, the semiconductor chip 100 is bonded to the circuit board 200 while the semiconductor chip 100 is pressed onto the circuit board 200, so the first to the fourth flexible beam portions 825a to 825d bend toward the core member 210 also in the completed semiconductor device.

Next, as illustrated in FIG. 27B, the solder balls 400 are respectively attached to the bottom surface electrodes 233 of the circuit board 200. In this way, the semiconductor device according to the third embodiment is completed.

Positioning Process of Semiconductor Chip

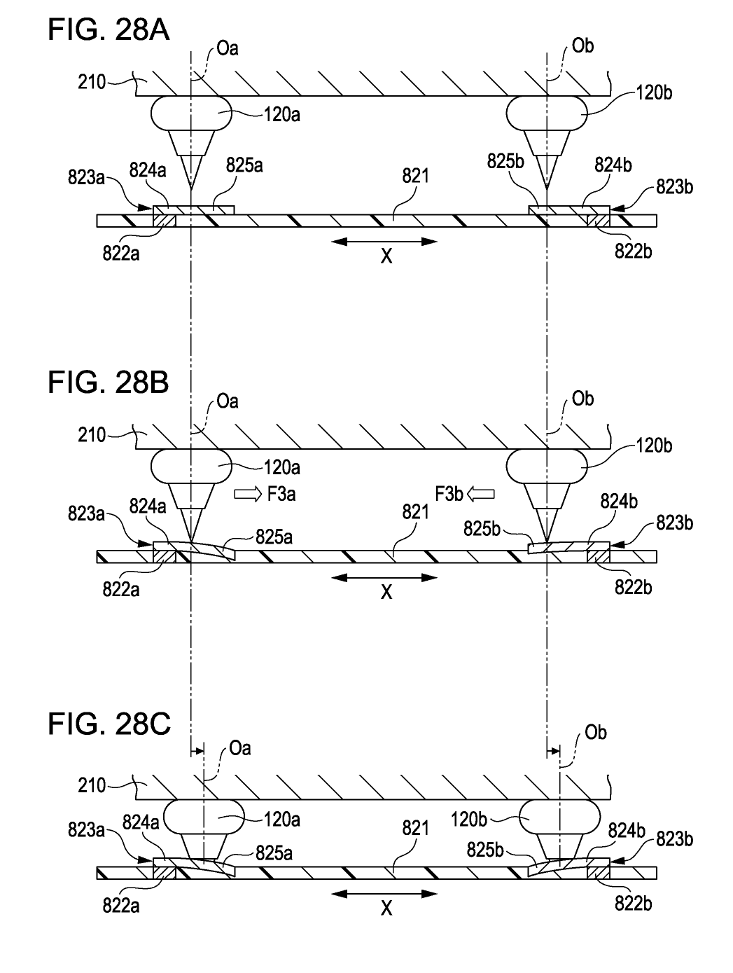

Next, the positioning process of the semiconductor chip 100 will be described with reference to FIGS. 28A to 28C.

FIGS. 28A to 28C are illustrations for explaining the positioning process of the semiconductor chip 100 according to the third embodiment, and illustrate the cooperation between the first and the second bumps 120a and 120b and the first and the second top surface electrodes 823a and 823b.

First, as illustrated in FIG. 28A, the pressure head H (not illustrated in FIG. 28A) that absorbs the semiconductor chip 100 is driven to position the semiconductor chip 100 so that the central axes Oa to Od of the first to the fourth bumps 120a to 120d are located over the first to the fourth flexible beam portions 825a to 825d.

Next, the pressure head H is lowered and the semiconductor chip 100 is moved closer to the circuit board 200. When the first to the fourth bumps 120a to 120d come into contact with the first to the fourth flexible beam portions 825a to 825d, the semiconductor chip 100 is started to be pressed onto the circuit board 200. Then, the first to the fourth flexible beam portions 825a to 825d bend closer to the core member 210 as the position moves to inner side of the circuit board 200. Thereby, as illustrated in FIG. 28B, first to fourth reaction forces F3a to F3d are respectively applied from the first to the fourth flexible beam portions 825a to 825d to the first to the fourth bumps 120a to 120d. At this time, if the semiconductor chip 100 is shifted toward the first board edge 210a (toward the left side in FIGS. 28A to 28C) in the X direction of the circuit board 200, the distance between the first post portion 822a and the first bump 120a is smaller than the distance between the second post portion 822b and the second bump 120b. In other words, the first bump 120a comes into contact with the first flexible beam portion 825a at a position near the first post portion 822a, and the second bump 120b comes into contact with the second flexible beam portion 825b at a position far from the second post portion 822b. Therefore, although the first and the second bumps 120a and 120b are lowered by the same amount, the first flexible beam portion 825a bends more than the second flexible beam portion 825b. Thereby the top surface of the first flexible beam portion 825a tilts by an angle larger than that of the top surface of the second flexible beam portion 825b. Therefore, the first reaction force F3a applied from the first flexible beam portion 825a to the first bump 120a is larger than the second reaction force F3b applied from the second flexible beam portion 825b to the second bump 120b. Thereby the first and the second bumps 120a and 120b move toward the second board edge 210b (toward the right side in FIGS. 28A to 28C) while sliding on the first and the second flexible beam portions 825a and 825b by a resultant force of the first and the second reaction forces F3a and F3b.

When the first and the second bumps 120a and 120b move toward the second board edge 210b, the deformations of the first and the second flexible beam portions 825a and 825b are gradually equalized. Then, as illustrated in FIG. 28C, when the distance from the first bump 120a to the first post portion 822a becomes the same as the distance from the second bump 120b to the second post portion 822b, the deformations of the first and the second flexible beam portions 825a and 825b become the same. Then, the first and the second reaction forces F3a and F3b applied to the first and the second bumps 120a and 120b are balanced and offset each other, so that the movement of the semiconductor chip 100 stops. In this way, the first and the second bumps 120a and 120b are accurately positioned in the longitudinal direction of the first and the second flexible beam portions 825a and 825b, that is, the X direction of the circuit board 200. When the first and the second bumps 120a to 120b are accurately positioned in the X direction of the circuit board 200, the semiconductor chip 100 is also accurately positioned in the X direction of the circuit board 200.

In this way, when the semiconductor chip 100 is accurately positioned in the X direction of the circuit board 200, in the same manner as in the first embodiment, the third and the fourth bumps 120c and 120d are also accurately positioned in the X direction of the circuit board 200. Specifically, the third and the fourth bumps 120c and 120d are accurately positioned in the width direction of the third and the fourth top surface electrodes 823c and 823d, that is, the direction perpendicular to the longitudinal direction. Therefore, even if the width of the third and the fourth top surface electrodes 823c and 823d decreases as the electrode pitch of the semiconductor chip 100 becomes finer, it is possible to reliably mount the third and the fourth bumps 120c and 120d on the third and the fourth top surface electrodes 823c and 823d. Further, when the semiconductor chip 100 is started to be pressed, the first and the second bumps 120a and 120b only have to be arranged on the first and the second flexible beam portions 825a and 825b. Thus the positioning operation is not difficult.

Although here, it is assumed that the semiconductor chip 100 is shifted toward the first board edge 210a (toward the left side in FIGS. 28A to 28C) in the X direction of the circuit board 200, if the semiconductor chip 100 is slightly shifted toward the second board edge 210b (toward the right side in FIGS. 28A to 28C) in the X direction of the circuit board 200, the positioning operation can be performed in the same manner as described above.

When the semiconductor chip 100 is accurately positioned in the X direction of the circuit board 200, the semiconductor chip 100 is further pressed onto the circuit board 200. Then the sharp top end portions of the first and the second bumps 120a and 120b are flattened and connected to the first and the second flexible beam portions 825a and 825b. At this time, the first and the second bumps 120a and 120b are respectively held on the tilted top surfaces of the first and the second flexible beam portions 825a and 825b. In other words, the first and the second reaction forces F3a and F3b are respectively applied to the first and the second bumps 120a and 120b. Therefore, while the semiconductor chip 100 is being pressed onto the circuit board 200, the position of the semiconductor chip 100 is not shifted in the X direction of the circuit board 200. Therefore, in the process for mounting the semiconductor chip 100 on the circuit board 200, the third and the fourth bumps 120c and 120d do not drop out of the third and the fourth flexible beam portions 825c and 825d.

Although the cooperation between the first and the second bumps 120a and 120b and the first and the second top surface electrodes 823a and 823b has been focused and described, this is the same for the cooperation between the third and the fourth bumps 120c and 120d and the third and the fourth top surface electrodes 823c and 823d.

For example, if the semiconductor chip 100 is shifted toward the third board edge 210c in the Y direction of the circuit board 200, the third reaction force F3c applied from the third flexible beam portion 825c to the third bump 120c is larger than the fourth reaction force F3d applied from the fourth flexible beam portion 825d to the fourth bump 120d. Thereby the third and the fourth bumps 120c and 120d move toward the fourth board edge 210d while sliding on the third and the fourth flexible beam portions 825c and 825d by a resultant force of the third and the fourth reaction forces F3c and F3d.

When the third and the fourth bumps 120c and 120d move toward the fourth board edge 210d, the deformations of the third and the fourth flexible beam portions 825c and 825d are gradually equalized. Then, when the distance from the third bump 120c to the third post portion 822c becomes the same as the distance from the fourth bump 120d to the fourth post portion 822d, the deformations of the third and the fourth flexible beam portions 825c and 825d become the same. Then, the third and the fourth reaction forces F3c and F3d applied to the third and the fourth bumps 120c and 120d are balanced and offset each other, so that the movement of the semiconductor chip 100 stops. In this way, the third and the fourth bumps 120c and 120d are accurately positioned in the longitudinal direction of the third and the fourth flexible beam portions 825c and 825d, that is, the Y direction of the circuit board 200. When the third and the fourth bumps 120c to 120d are positioned in the Y direction of the circuit board 200, the semiconductor chip 100 is also accurately positioned in the Y direction of the circuit board 200.

In this way, when the semiconductor chip 100 is accurately positioned in the Y direction of the circuit board 200, in the same manner as in the first embodiment, the first and the second bumps 120a and 120b are also accurately positioned in the Y direction of the circuit board 200. Specifically, the first and the second bumps 120a and 120b are accurately positioned in the width direction of the first and the second top surface electrodes 823a and 823b, that is, the direction perpendicular to the longitudinal direction. Therefore, even if the width of the first and the second top surface electrodes 823a and 823b decreases as the electrode pitch of the semiconductor chip 100 becomes finer, it is possible to reliably mount the first and the second bumps 120a and 120b on the first and the second top surface electrodes 823a and 823b. Further, when the semiconductor chip 100 is started to be pressed, the third and the fourth bumps 120c and 120d only have to be arranged on the third and the fourth flexible beam portions 825c and 825d. Thus the positioning operation is not difficult.

Although here, it is assumed that the semiconductor chip 100 is shifted toward the third board edge 210c in the Y direction of the circuit board 200, if the semiconductor chip 100 is slightly shifted toward the fourth board edge 210d in the Y direction of the circuit board 200, the positioning operation can be performed in the same manner as described above.

When the semiconductor chip 100 is accurately positioned in the Y direction of the circuit board 200, the semiconductor chip 100 is further pressed onto the circuit board 200. Then the sharp top end portions of the third and the fourth bumps 120c and 120d are flattened and connected to the third and the fourth flexible beam portions 825c and 825d. At this time, the third and the fourth bumps 120c and 120d are respectively held on the tilted top surfaces of the third and the fourth flexible beam portions 825c and 825d. In other words, the third and the fourth reaction forces F3c and F3d are respectively applied to the third and the fourth bumps 120c and 120d. Therefore, while the semiconductor chip 100 is being pressed onto the circuit board 200, the position of the semiconductor chip 100 is not shifted in the Y direction of the circuit board 200. Therefore, in the process for mounting the semiconductor chip 100 on the circuit board 200, the first and the second bumps 120a and 120b do not drop out of the first and the second flexible beam portions 825a and 825b.

Although here the positioning in the X direction and the positioning in the Y direction of the semiconductor chip 100 are separately described, the positioning in the X direction and the positioning in the Y direction of the semiconductor chip 100 progress simultaneously.

As described above, in the present embodiment, even when the semiconductor chip 100 is slightly shifted in the X direction or the Y direction of the circuit board 200, in the process for moving the semiconductor chip 100 closer to the circuit board 200, the position of the semiconductor chip 100 is gradually corrected and the semiconductor chip 100 is accurately positioned. Specifically, when the semiconductor chip 100 is moved closer to the circuit board 200, the first to the fourth bumps 120a to 120d automatically approach the correct positions thereof and the semiconductor chip 100 is accurately positioned. Further, the first to the fourth bumps 120a to 120d are held on the tilted top surfaces of the first to the fourth flexible beam portions 825a to 825d, so the semiconductor chip 100 does not shift in the process for pressing the semiconductor chip 100 onto the circuit board 200. As a result, the first to the fourth bumps 120a to 120d do not drop out of the first to the fourth flexible beam portions 825a to 825d.

According to the present embodiment, the semiconductor chip 100 can be accurately positioned only by providing the first to the fourth fixed portions 824a to 824d arranged on the first to the fourth post portions 822a to 822d and the first to the fourth flexible beam portions 825a to 825d arranged on the deformation absorption film 821 to the first to the fourth top surface electrodes 823a to 823d. Therefore, the first to the fourth top surface electrodes 823a to 823d formed on the circuit board 200 need not be widened. Therefore, it is possible to make the electrode pitch of the semiconductor chip 100 much finer.

In the present embodiment, as a material of the deformation absorption film 821, a material having rigidity lower than that of the first to the fourth post portions 822a to 822d is used. However, the material needs to have rigidity lower than that of the first to the fourth post portions 822a to 822d only when the semiconductor chip 100 is mounted. For example, if a thermoplastic resin is used as the material of the deformation absorption film 821, the thermoplastic resin softens when the semiconductor chip 100 is heated, so the first to the fourth flexible beam portions 825a to 825d bend more easily. Further, when the temperature of the deformation absorption film 821 drops after the heating of the semiconductor chip 100, the deformation absorption film 821 automatically hardens, so it is possible to provide desired strength to the circuit board 200 even after the completion of the semiconductor device. However, the material needs to be selected so that the deformation absorption film 821 does not soften or liquefy by the heat generated when the semiconductor device is actually used. If a B-stage resin is used as the material of the deformation absorption film 821, the deformation absorption film 821 transitions to a B-stage resin and softens when the semiconductor chip 100 is heated, so the first to the fourth flexible beam portions 825a to 825d bend more easily. In addition, when the semiconductor chip 100 is further heated, the deformation absorption film 821 transitions to C-stage and hardens naturally, so it is possible to provide desired strength to the circuit board 200 even after the completion of the semiconductor device. However, the material needs to be selected so that the heating temperature of the semiconductor chip 100 corresponds to the temperature at which the deformation absorption film 821 transitions to B-stage, that is, the B-stage temperature.

### Modified Example

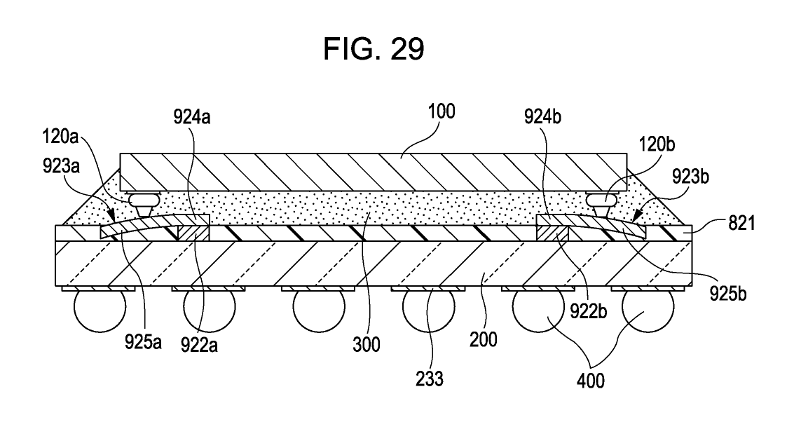

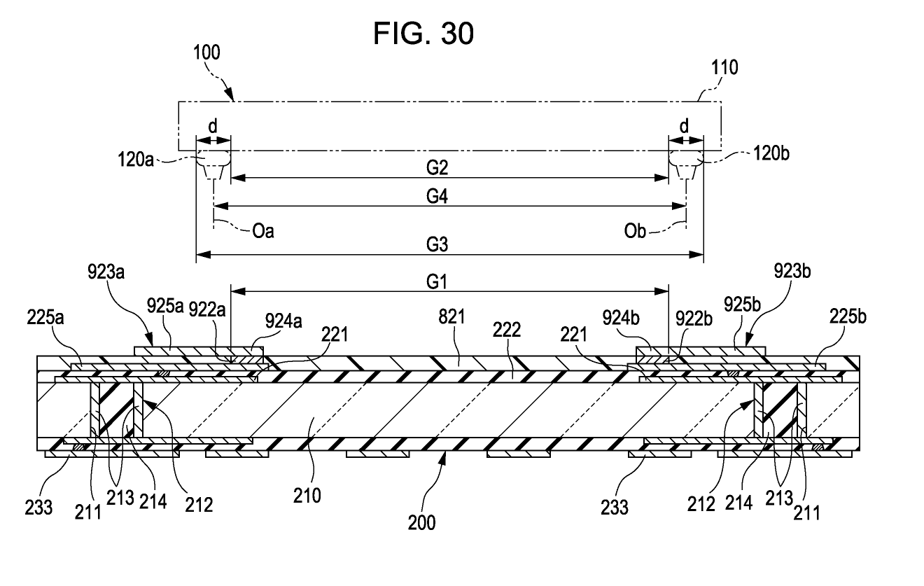

Hereinafter, a modified example of the third embodiment will be described with reference to FIGS. 29 to 30.

FIG. 29 is a cross-sectional view of a semiconductor device according to the modified example of the third embodiment and illustrates a cross-section corresponding to FIG. 22. FIG. 30 is a cross-sectional view of the circuit board 200 according to the modified example of the third embodiment and illustrates a cross-section corresponding to FIG. 24.

First to fourth top surface electrodes 923a to 923d according to the present modified example extend toward the opposite side of those in the third embodiment with respect to first to fourth post portions 922a to 922d, that is, toward the outside of the circuit board 200. Specifically, the first to the fourth top surface electrodes 923a to 923d include first to fourth fixed portions 924a to 924d arranged on the first to the fourth post portions 922a to 922d and first to fourth flexible beam portions 925a to 925d which are arranged on the deformation absorption film 821 and extend from the first to the fourth fixed portions 924a to 924d toward the outside of the circuit board 200.

The first to the fourth bumps 120a to 120d of the semiconductor chip 100 are respectively mounted on the first to the fourth flexible beam portions 925a to 925d. Therefore, the distance G1 between the outer side surface of the first post portion 922a and the outer side surface of the second post portion 922b is set to be smaller than the distance G4 between the central axis Oa of the first bump 120a and the central axis Ob of the second bump 120b. More preferably, the distance G1 between the outer side surface of the first post portion 922a and the outer side surface of the second post portion 922b is set to be smaller than the distance G2 between the first bump 120a and the second bump 120b. When employing the above distances, the entire portions of the first and the second bumps 120a and 120b can be connected to the first and the second flexible beam portions 925a and 925b. Specifically, the semiconductor chip 100 can be positioned so that the first and the second bumps 120a and 120b are not connected to the first and the second fixed portions 924a and 924b. Similarly, the distance G1 between the outer side surface of the third post portion 922c and the outer side surface of the fourth post portion 922d is set to be smaller than the distance G4 between the central axis Oc of the third bump 120c and the central axis Od of the fourth bump 120d. More preferably, the distance G1 between the outer side surface of the third post portion 922c and the outer side surface of the fourth post portion 922d is set to be smaller than the distance G2 between the third bump 120c and the fourth bump 120d. When employing the above distances, the entire portions of the third and the fourth bumps 120c and 120d can be connected to the third and the fourth flexible beam portions 925c and 925d. Specifically, the semiconductor chip 100 can be positioned so that the third and the fourth bumps 120c and 120d are not connected to the third and the fourth fixed portions 924c and 924d.

As described in the present modified example, the first to the fourth top surface electrodes 923a to 923d may extend toward the opposite side of those in the third embodiment with respect to the first to the fourth post portions 922a to 922d. When employing the present modified example, if the semiconductor chip 100 is positioned so that the central axes Oa to Od of the first to the fourth bumps 120a to 120d are located on the first to the fourth flexible beam portions 925a to 925d, and the semiconductor chip 100 is pressed onto the circuit board 200, the semiconductor chip 100 can be accurately positioned as described above. However, the first to the fourth flexible beam portions 925a to 925d tilt in the direction opposite to that in which the first to the fourth flexible beam portions 825a to 825d according to the third embodiment tilt, so the first to the fourth reaction forces according to the present modified example are applied in directions opposite to the directions of the first to the fourth reaction forces according to the third embodiment.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic device comprising:
a circuit board including a first electrode and a second electrode; and
an electronic component including a first terminal and a second terminal,
wherein the first electrode includes a first pad portion to which the first terminal is connected and a first protrusion portion disposed in a first direction in parallel with a straight line passing through the first electrode and the second electrode with respect to the first pad portion and being into contact with the first terminal,
the second electrode includes a second pad portion to which the second terminal is connected and a second protrusion portion disposed in a second direction opposite to the first direction with respect to the second pad portion and being into contact with the second terminal,
a central axis of the first terminal is disposed on a side of the first pad portion with respect to the first protrusion portion, and
a central axis of the second terminal is disposed on a side of the second pad portion with respect to the second protrusion portion.

2. An electronic device comprising:
a circuit board including a first electrode and a second electrode which are disposed on a first straight line and a third electrode and a fourth electrode which are disposed on a second straight line with interposing the first straight line, the second straight line crossing the first straight line between the first electrode and the second electrode; and
an electronic component including a first terminal, a second terminal, a third terminal and a fourth terminal;
wherein the first electrode includes a first pad portion to which the first terminal is connected and a first protrusion portion disposed on a first side of the first pad portion and being into contact with the first terminal, the first side being corresponding to a side on which the third electrode is disposed with respect to the first straight line,
the second electrode includes a second pad portion to which the second terminal is connected and a second protrusion portion disposed on a second side of the second pad portion and being into contact with the second terminal, the second side being corresponding to a side on which the fourth electrode is disposed with respect to the first straight line,
the third electrode includes a third pad portion to which the third terminal is connected and a third protrusion portion disposed on a third side of the third pad portion and being into contact with the third terminal, the third side being corresponding to a side on which the first electrode is disposed with respect to the second straight line,
the fourth electrode includes a fourth pad portion to which the fourth terminal is connected and a fourth protrusion portion disposed on a fourth side of the fourth pad portion and being into contact with the fourth terminal, the fourth side being corresponding to a side on which the second electrode is disposed with respect to the second straight line,
a central axis of the first terminal is disposed on a side of the first pad portion with respect to the first protrusion portion,
a central axis of the second terminal is disposed on a side of the second pad portion with respect to the second protrusion portion,
a central axis of the third terminal is disposed on a side of the third pad portion with respect to the third protrusion portion, and
a central axis of the fourth terminal is disposed on a side of the fourth pad portion with respect to the fourth protrusion portion.

3. An electronic device comprising:
a circuit board; and
an electronic component mounted on the circuit board;
wherein the circuit board includes
a base member,
a first support body and a second support body which are disposed above the base member,
a first electrode including a first fixed portion disposed on the first support body, and a first beam portion disposed in a first direction in parallel with a straight line passing through the first support body and the second support body with respect to the first fixed portion,
a second electrode including a second fixed portion disposed on the second support body, and a second beam portion disposed in a second direction opposite to the first direction with respect to the second fixed portion, and
a film which is disposed under the first beam portion and the second beam portion and has rigidity lower than that of the first support body and the second support body, and
the electronic component includes
a body portion,
a first terminal provided on the body portion and connected to the first beam portion, and
a second terminal provided on the body portion and connected to the second beam portion.

4. The electronic device according to claim 3,
wherein the first beam portion bends so that the first beam portion gets closer to the base member with increasing a distance from the first support body in the first direction, and
the second beam portion bends so that the second beam portion gets closer to the base member with increasing a distance from the second support body in the second direction.

5. The electronic device according to claim 3,
wherein the film is formed of a thermoplastic resin.

6. The electronic device according to claim 3,
wherein the film is formed of a B-stage resin.

7. A circuit board on which an electronic component is to be mounted, the circuit board comprising:
a base member; and
a first electrode and a second electrode disposed above the base member;
wherein the first electrode includes a first pad portion to which a first terminal of the electronic component is to be connected and a first protrusion portion disposed in a first direction in parallel with a first straight line passing through the first electrode and the second electrode with respect to the first pad portion and being for pressing a side surface of the first terminal toward the first pad portion upon being pressed by the first terminal, and
the second electrode includes a second pad portion to which a second terminal of the electronic component is to be connected and a second protrusion portion disposed in a second direction opposite to the first direction with respect to the second pad portion and being for pressing a side surface of the second terminal toward the second pad portion upon being pressed by the second terminal.

8. A circuit board on which an electronic component is to be mounted, the circuit board comprising:
a base member; and
a first electrode and a second electrode disposed on a first straight line defined above the base member and a third electrode and a fourth electrode disposed on a second straight line with interposing the first straight line, the second straight line crossing the first straight line between the first electrode and the second electrode;
wherein the first electrode includes a first pad portion to which a first terminal of the electronic component is to be connected and a first protrusion portion disposed on a first side of the first pad portion and being for pressing a side surface of the first terminal toward the first pad portion upon being pressed by the first terminal, the first side being corresponding to a side on which the third electrode is disposed with respect to the first straight line, and
the second electrode includes a second pad portion to which a second terminal of the electronic component is to be connected and a second protrusion portion disposed on a second side of the second pad portion and being for pressing a side surface of the second terminal toward the second pad portion upon being pressed by the second terminal, the second side being corresponding to a side on which the fourth electrode is disposed with respect to the first straight line,
the third electrode includes a third pad portion to which a third terminal of the electronic component is to be connected and a third protrusion portion disposed on a third side of the third pad portion and being for pressing a side surface of the third terminal toward the third pad portion upon being pressed by the third terminal, the third side being corresponding to a side on which the first electrode is disposed with respect to the second straight line, and
the fourth electrode includes a fourth pad portion to which a fourth terminal of the electronic component is to be connected and a fourth protrusion portion disposed on a fourth side of the fourth pad portion and being for pressing a side surface of the fourth terminal toward the fourth pad portion upon being pressed by the fourth terminal, the fourth side being corresponding to a side on which the second electrode is disposed with respect to the second straight line.

9. A circuit board on which an electronic component is mounted, the circuit board comprising:
a base member;
a first support body and a second support body disposed above the base member;
a first electrode including a first fixed portion disposed on the first support body, and a first beam portion to which a first terminal of the electronic component is connected, the first beam portion being disposed in a first direction in parallel with a straight line passing through the first support body and the second support body with respect to the first fixed portion and being for pressing the first terminal in the first direction by bending so that the first beam portion gets closer to the base member with increasing a distance from the first fixed portion upon being pressed by the first terminal;
a second electrode including a second fixed portion disposed on the second support body, and a second beam portion to which a second terminal of the electronic component is connected, the second beam portion being disposed in a second direction opposite to the first direction with respect to the second fixed portion and being for pressing a second terminal in the second direction by bending so that the second beam portion gets closer to the base member with increasing a distance from the second fixed portion upon being pressed by the second terminal; and
a film which is disposed under the first beam portion and the second beam portion and has rigidity lower than that of the first support body and the second support body.

10. The circuit board according to claim 9,
wherein the film is formed of a thermoplastic resin.

11. The circuit board according to claim 9,
wherein the film is formed of a B-stage resin.

12. A method for manufacturing an electronic device, the method comprising:
causing a first terminal and a second terminal of an electronic component to respectively come into contact with a first electrode and a second electrode which are formed on a circuit board, the first electrode being for applying a first reaction force in parallel with a mounting surface of the circuit board to the first terminal upon being pressed by the first terminal, the second electrode being for applying a second reaction force to offset the first reaction force to the second terminal upon being pressed by the second terminal; and
pressing the first terminal and the second terminal to the first electrode and the second electrode.

13. The method for manufacturing an electronic device according to claim 12,
wherein the pressing the first terminal and the second terminal to the first electrode and the second electrode causes a side surface of the first terminal and a side surface of the second terminal to respectively come into contact with a first side portion of a first protrusion portion formed on the first electrode and a second side portion of a second protrusion portion formed on the second electrode, the first side portion being located in a first direction in parallel with a first straight line passing through the first electrode and the second electrode in the first protrusion portion, the second side portion being located in a second direction opposite to the first direction in the second protrusion portion.

14. The method for manufacturing an electronic device according to claim 12,
wherein the causing a first terminal and a second terminal of an electronic component to respectively come into contact with a first electrode and a second electrode causes a third terminal and a fourth terminal of the electronic component to respectively come into contact with a third electrode and a forth electrode which are formed on the circuit board, the third electrode being for applying a third reaction force to the third terminal upon being pressed by the third terminal, the third reaction force being in parallel with the mounting surface and crossing the first reaction force and the second reaction force, the fourth electrode being for applying a fourth reaction force to offset the third reaction force to the fourth terminal upon being pressed by the fourth terminal, and
the pressing the first terminal and the second terminal to the first electrode and the second electrode includes pressing the third terminal and the fourth terminal to the third electrode and the fourth electrode.

15. The method for manufacturing an electronic device according to claim 14,
wherein the first electrode and the second electrode are disposed on a first straight line and the third electrode and the fourth electrode are disposed on a second straight line with interposing the first straight line, the second straight line crossing the first straight between the first electrode and the second electrode, and
the pressing the first terminal and the second terminal to the first electrode and the second electrode causes a side surface of the first terminal, a side surface of the second terminal, a side surface of the third terminal and a side surface of the fourth terminal to respectively come into contact with a first side portion of a first protrusion portion formed on the first electrode, a second side portion of a second protrusion portion formed on the second electrode, a third side portion of a third protrusion portion formed on the first electrode and a fourth side portion of a fourth protrusion portion formed on the first electrode, the first side portion being located in a first rotation direction around a crossing point of the first straight line and the second straight line in the first protrusion portion, the second portion being located in the first rotation direction around the crossing point in the second protrusion portion, the third portion being located in a second rotation direction opposite to the first rotation direction around the crossing point in the third protrusion portion, the fourth portion being located in the second rotation direction around the crossing point in the fourth protrusion portion.

16. The method for manufacturing an electronic device according to claim 12,
wherein the pressing the first terminal and the second terminal to the first electrode and the second electrode includes bending the first electrode and the second electrode by a pressing force of the first terminal and a pressing force of the second terminal to tilt the top surface of the first electrode and a top surface of the second electrode with respect to the mounting surface in opposite directions.

17. The method for manufacturing an electronic device according to claim 12,
wherein the pressing the first terminal and the second terminal to the first electrode and the second electrode includes bonding the electronic component to the circuit board while pressing the first terminal and the second terminal to the first electrode and the second electrode.

18. The method for manufacturing an electronic device according to claim 17, further comprising:
providing a fluidal resin material between the circuit board and the electronic component before pressing the first terminal and the second terminal to the first electrode and the second electrode;
wherein the pressing the first terminal and the second terminal to the first electrode and the second electrode includes bonding the electronic component to the circuit board by hardening the resin material while pressing the first terminal and the second terminal to the first electrode and the second electrode.

19. The method for manufacturing an electronic device according to claim 18,
wherein the hardening the resin material includes heating the resin material.
